(19) United States
(12) Patent Application Publication
(10) Pub. No.: US 2026/0128750 A1
(43) Pub. Date: May 7, 2026

(54) DATA-DRIVEN NEURAL POLAR DECODER

(71) Applicants: B. G. NEGEV TECHNOLOGIES AND APPLICATIONS LTD., Beer-Sheva (IL); DUKE UNIVERSITY, Durham, NC (US)

(72) Inventors: Bashar HULEIHEL, Beer-Sheva (IL); Ziv AHARONI, Beer-Sheva (IL); Haim Henry PERMUTER, Beer-Sheva (IL); Henry PFISTER, Durham, NC (US)

(21) Appl. No.: 19/481,234

(22) PCT Filed: May 9, 2024
(86) PCT No.: PCT/IL2024/050454

§ 371 Date: Nov. 4, 2025

Related U.S. Application Data
(60) Provisional application No. 63/465,258, filed on May 10, 2023.

(51) Int. Cl. H03M 13/13

(52) U.S. Cl. CPC H03M 13/13

(57) ABSTRACT

A method comprising: using a neural successive cancellation (NSC) polar codes decoder for communication or decompression, wherein the NSC polar codes decoder comprises the following Artificial Neural Networks (ANNs): (a) when the NSC polar codes decoder is used for communication: an output statistics ANN; (b) when the NSC polar codes decoder is used for decompression: an input statistics ANN; (c) a check-node ANN; (d) a bit-node ANN; and (e) a soft decision operations ANN.

### CROSS-REFERENCE TO RELATED APPLICATION

This application claims priority to U.S. Provisional Patent Application No. 63/465,258, filed May 10, 2023, entitled “Data Driven Polar Codes,” the contents of which are incorporated herein by reference in their entirety.

### FIELD

The invention relates to the field of error detection and correction (EDAC), and more specifically to polar codes.

### BACKGROUND

Polar codes are a type of error-correction codes introduced by Erdal Arikan in “Channel Polarization: A Method for Constructing Capacity-Achieving Codes for Symmetric Binary-Input Memoryless Channels,” IEEE Transactions on Information Theory, 55(7):3051-3073, 2009. Throughout this disclosure, any reference to Arikan is to his aforementioned paper, unless explicitly mentioned otherwise.

Polar codes allow the construction of capacity-achieving codes for symmetric binary-input, discrete, memoryless channels (B-DMCs). When given N independent copies of a B-DMC W, successive cancellation (SC) decoding induces a new set of N binary-input synthesized (virtual) channels

$${W}_{N}^{( i )} .$$

Channel polarization is the phenomenon identified by Arikan, whereby, for N sufficiently large, almost all of the synthesized channels

$${W}_{N}^{( i )}$$

have capacities close to 0 or 1. Specifically, the fraction of channels with capacity close to 1 approaches I(W) and the fraction of channels with capacity close to 0 approaches 1−I(W), where I(W) is the channel's symmetric capacity.

The construction of polar codes involves choosing which rows to keep from the square generator matrix given by Arikan's transform, such that the polar codes ultimately allocate data bits to the most reliable, clean channels—those whose capacity approaches 1.

The encoding and decoding procedures are performed by recursive formulas whose computational complexity is O(N log N).

Polar codes can also be applied to finite state channels (FSCs). Arikan's transform also polarizes the bit channels

$${W}_{N}^{( i )}$$

in the presence of memory (see E. Sasoglu and I. Tal, “Polar Coding for Processes with Memory,” IEEE Trans. Inf. Theory, vol. 65, no. 4, pp. 1994-2003, 2019; and B. Shuval and I. Tal, “Fast Polarization for Processes with Memory,” IEEE Trans. Inf. Theory, vol. 65, no. 4, pp. 2004-2020, 2018), and thus the encoding algorithm is the same as if the channel is memoryless. However, the decoding algorithm needs to be updated since the derivation of the SC decoder in Arikan relies on the memoryless property. To account for the channel memory, the channel outputs are represented by a trellis, whose nodes capture the information of the channel's memory. This trellis was embedded into the SC decoding algorithm to yield the SCT decoding algorithm (see R. Liu and Y. Hou, “Joint Successive Cancellation Decoding of Polar Codes Over Intersymbol Interference Channels,” arXiv:1404.3001, 2014; and R. Wang, J. Honda, H. Yamamoto, R. Liu, and Y. Hou, “Construction of polar codes for channels with memory,” 2015 IEEE Information Theory Workshop—Fall, IEEE, pp. 187-191, 2015).

However, the SCT decoder is only applicable when the channel model is known and when the channel's state alphabet size is finite and relatively small. For FSCs the computational complexity of the SCT decoder is O(| [symbol] |³N log N), where | [symbol] | is the number of channel states. For Markov channels where the set of channel states is not finite, the SCT decoder is not applicable without quantization of its states. With quantization, there may be a strong tension between the computational complexity and the error introduced by quantization. Additionally, the SCT decoder cannot be used for an unknown channel with memory without first estimating the channel, as it requires an explicit channel model.

The SCT decoder can also be applied to a larger class of channels (e.g., insertion and deletion channels) where, given the channel output sequence Y^{N}, a trellis can be constructed to efficiently represent P_{X}_{^{N}}_{,Y}_{^{N}} (see I. Tal, H. D. Pfister, A. Fazeli, and A. Vardy, “Polar Codes for the Deletion Channel: Weak and Strong Polarization,” IEEE Trans. Inf. Theory, vol. 68, no. 4 pp 2239-2265, 2021). In that case, the decoding complexity is upper bounded by O(| [symbol] |³N log N), where |S| is the maximum number of states in any trellis stage. If | [symbol] |grows linearly with N, then the complexity of the decoder may grow very rapidly (e.g., ≥N⁴) and is dominated by the number of trellis states rather than the block length.

Today, most notably, polar codes are used for certain aspects of channel coding in 3GPP's fifth-generation (5G) cellular communications standard, and are embedded in various 5G network appliances, such as base stations and end-user devices. Polar codes remain attractive for various other technologies as well.

The foregoing examples of the related art and limitations related therewith are intended to be illustrative and not exclusive. Other limitations of the related art will become apparent to those of skill in the art upon a reading of the specification and a study of the figures.

### SUMMARY

The following embodiments and aspects thereof are described and illustrated in conjunction with systems, tools and methods which are meant to be exemplary and illustrative, not limiting in scope.

One embodiment provides a method comprising: using a neural successive cancellation (NSC) polar codes decoder for communication or decompression, wherein the NSC polar codes decoder comprises the following Artificial Neural Networks (ANNs): (a) when the NSC polar codes decoder is used for communication: an output statistics ANN; (b) when the NSC polar codes decoder is used for decompression: an input statistics ANN; (c) a check-node ANN; (d) a bit-node ANN; and (e) a soft decision operations ANN.

Another embodiment provides a system comprising at least one hardware processor, and a non-transitory computer-readable storage medium having program code embodied therewith, the program code executable by said at least one hardware processor to use a neural successive cancellation (NSC) polar codes decoder for communication or decompression, wherein the NSC polar codes decoder comprises the following Artificial Neural Networks (ANNs): (a) when the NSC polar codes decoder is used for communication: an output statistics ANN; (b) when the NSC polar codes decoder is used for decompression: an input statistics ANN; (c) a check-node ANN; (d) a bit-node ANN; and (e) a soft decision operations ANN.

A further embodiment provides a computer program product comprising a non-transitory computer-readable storage medium having program code embodied therewith, the program code executable by at least one hardware processor to use a neural successive cancellation (NSC) polar codes decoder for communication or decompression, wherein the NSC polar codes decoder comprises the following Artificial Neural Networks (ANNs): (a) when the NSC polar codes decoder is used for communication: an output statistics ANN; (b) when the NSC polar codes decoder is used for decompression: an input statistics ANN; (c) a check-node ANN; (d) a bit-node ANN; and (e) a soft decision operations ANN.

An additional embodiment provides a semiconductor Integrated Circuit (IC) comprising: a neural successive cancellation (NSC) polar codes decoder configured with the following Artificial Neural Networks (ANNs): (a) an output statistics ANN, (b) a check-node ANN, (c) a bit-node ANN, and (d) a soft decision operations ANN; and a polar codes encoder configured to encode data using polar codes designed based on the NSC polar codes decoder.

Yet another embodiment provides a computer-readable medium having stored thereon a computer-readable encoding of the semiconductor integrated circuit (IC).

In some embodiments, the NSC polar codes decoder is used for decompression, and wherein the method further comprises designing polar codes to compress data, the designing being based on the NSC polar codes decoder.

In some embodiments, the method further comprises, or the program code is further executable for, training the ANNs to decompress the compressed data.

In some embodiments, the NSC polar codes decoder is used for communication, and wherein the method further comprises designing polar codes to encode data to be transmitted over multiple communication channels, the designing being based on the NSC polar codes decoder.

In some embodiments, the method further comprises, or the program code is further executable for, training the ANNs to decode the data after the data have been received over the multiple communication channels.

In some embodiments, the training comprises determining parameters for the ANNs by estimating mutual information (MI) for each of the multiple communication channels.

In some embodiments, the designing of the polar codes comprises determining, using a Monte Carlo (MC) evaluation, which of the multiple communication channels are clean.

In some embodiments, the ANNs of (a) or (b), (c), (d), and (e) are trained jointly.

In some embodiments, the ANN of (a) or (b) is trained first, and the ANNs of (c), (d), and (e) are then trained while maintaining the determined parameters of the ANN of (a) or (b), respectively, fixed.

In some embodiments, a channel model of each of the multiple communication channels is unknown.

In some embodiments, the multiple communication channels are communication channels with memory; and a computational complexity of the NSC polar codes decoder is not affected by the size of the memory.

In some embodiments, the semiconductor IC further comprises circuitry to train the ANNs of the NSC polar codes decoder.

In some embodiments, the polar codes encoder is configured to design the polar codes by determining, using a Monte Carlo (MC) evaluation, which of the multiple communication channels are clean.

In addition to the exemplary aspects and embodiments described above, further aspects and embodiments will become apparent by reference to the figures and by study of the following detailed description.

### BRIEF DESCRIPTION OF THE FIGURES

Exemplary embodiments are illustrated in referenced figures. Dimensions of components and features shown in the figures are generally chosen for convenience and clarity of presentation and are not necessarily shown to scale. The figures are listed below.

FIG. 1 is a block diagram of an exemplary system for neural successive cancellation (NSC) polar codes decoding and polar codes design, according to an embodiment.

FIG. 2 is a flow diagram illustrating recursive loss computation by an NSC polar codes decoder, according to an embodiment.

FIG. 3 is a flowchart of a method for using an NSC polar codes decoder for communication or decompression, according to an embodiment.

FIGS. 4A and 4B show the application of Algorithm 1 on the BSC and AWGN channels, according to experimental results.

FIGS. 5A and 5B show the application of an extension of Algorithm 1 to the Honda-Yamamoto scheme, according to experimental results.

FIGS. 6A-6D compare the bit error rates attained by Algorithm 3 vs. the SCT decoder for the AWGN, Ising, ISI, and MA-AGN channels, respectively, according to experimental results.

FIGS. 7A and 7B illustrate, respectively, the bit error rates attained by Algorithm 4 on the Ising channel with an input distribution with memory, and the polarization of the synthesized bit channels for the Ising channel, according to experimental results.

FIGS. 8A and 8B illustrate, respectively, the bit error rates incurred for varying values of the block length in training, and the cross-entropy convergence as a function of training iterations, according to experimental results.

FIG. 9 compares the complexity of the NSC and SCT decoders and demonstrates the decoding performance of both decoders on the ISI channel, according to experimental results.

FIGS. 10A and 10B compare the performance of an NSC list decoder with that of the SCL decoder on the AWGN and Ising channels, respectively, according to experimental results.

### DETAILED DESCRIPTION

Disclosed herein is a technique, embodied in a method, a system, and a computer program product, that utilizes an advantageous neural successive cancellation (NSC) polar codes decoder for communication or compression. The NSC polar codes decoder may include multiple Artificial Neural Networks, three of which are essentially used in lieu of the three components of a traditional (non-neural) SC polar codes decoder: a check-node ANN, a bit-node ANN, and a soft decision operations ANN. In addition, depending on whether the neural NSC polar codes decoder is to be used for communication or decompression, it may further include an output statistics ANN (in the case of communication) or an input statistics ANN (in the case of decompression).

In the communication use case, the technique requires no information as to a channel model of any underlying communication channels, and essentially treats these channels as a “black box.” Further in the communication use case, the technique may include designing polar codes, based on the NSC polar codes decoder, to encode data to be transmitted over multiple communication channels. The ANNs which make up the NSC polar codes decoder may be trained to decode the data after the data have been received over the multiple communication channels. The training may include determining parameters for the ANNs by estimating mutual information (MI) for each of the multiple communication channels. The ANNs may be trained jointly or separately; if trained separately, the output statistics ANN may be trained first, and the check-node, bit-node, and soft decision operations ANNs are then trained while maintaining the determined parameters of the output statistics ANN fixed.

The technique may be useful both for communication channels without memory as well as for those with memory. In case the channels are with memory, an advantage of the technique is that a computational complexity of the NSC polar codes decoder is not affected by the size of the memory.

In the compression use case, the technique may include designing polar codes, based on the NSC polar codes decoder, to compress data. The ANNs which make up the NSC polar codes decoder may be trained to decompress the compressed data.

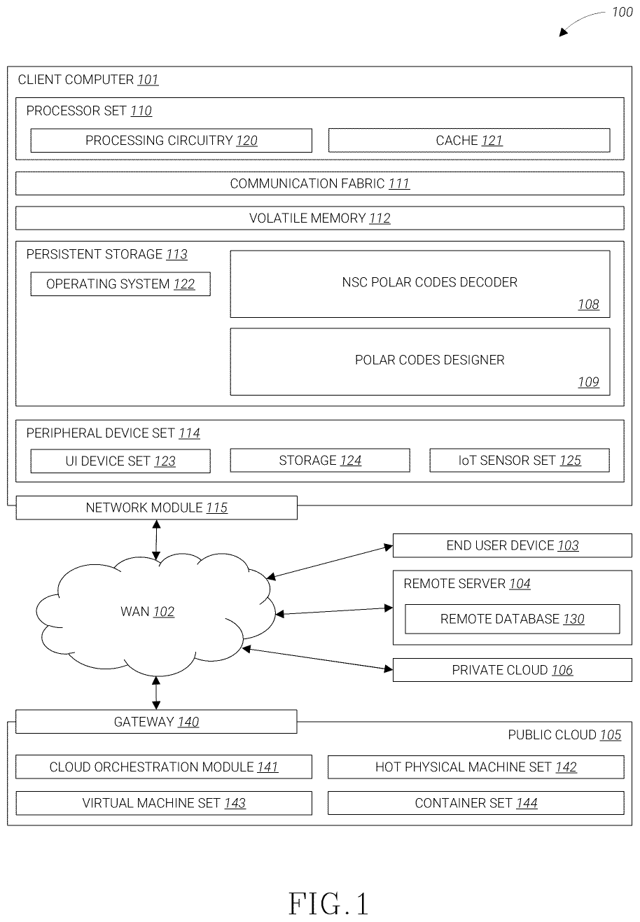

Reference is now made to FIG. 1, which shows a block diagram of an exemplary computing environment (also “system”) 100, containing an example of an environment for the execution of at least some of the computer code involved in performing the inventive methods, such as a NSC polar codes decoder block 108 and a polar codes designer block 109. In addition to blocks 108 and 109, computing environment 100 includes, for example, a computer 101, a wide area network (WAN) 102, an end user device (EUD) 103, a remote server 104, a public cloud 105, and/or a private cloud 106. In this example, computer 101 includes a processor set 110 (including processing circuitry 120 and a cache 121), a communication fabric 111, a volatile memory 112, a persistent storage 113 (including an operating system 122 and block 200, as identified above), a peripheral device set 114 (including a user interface (UI), a device set 123, a storage 124, and an Internet of Things (IoT) sensor set 125), and a network module 115. Remote server 104 includes a remote database 130. Public cloud 105 includes a gateway 140, a cloud orchestration module 141, a host physical machine set 142, a virtual machine set 143, and a container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network and/or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one or more computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the method(s) specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

Communication fabric 111 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, the volatile memory is characterized by random access, but this is not required unless affirmatively indicated. In computer 101, volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read-only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open source Portable Operating System Interface type operating systems that employ a kernel. The code included in block 200 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the Internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as a network interrace controller (NIC), a modem, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through the hardware included in network module 115.

WAN 102 is any wide area network (for example, the Internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the Internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

As a complete or a partial alternative to computing environment 100, the computer code involved in performing the inventive methods, such as the computer code of NSC polar codes decoder block 108 and/or polar codes designer block 109, may be embodied in or otherwise executed by a semiconductor Integrated Circuit (IC), such as an ASIC (Application-Specific Integrated Circuit), a FPGA (Field-Programmable Gate Arrays), etc. For example, the computer code involved in performing the inventive methods may be embodied in circuitry of an IC which serves as a communication encoder/decoder, such as a communication modem or chipset used for wireless or wired communication. While such IC embodiment generally assumes the existence of circuits and physical structures, it is well recognized that in modern semiconductor design and fabrication, physical structures and circuits may be embodied in computer readable descriptive form suitable for use in subsequent design, test or fabrication stages as well as in resultant fabricated semiconductor ICs. Accordingly, the IC embodiment is also intended to read upon computer readable encodings (which may be termed “programs”) and representations of same, whether embodied in non-transitory media or combined with suitable reader facilities to allow fabrication, test, or design refinement of the corresponding circuits and/or structures.

The following description discusses the instructions (provided, e.g., as computer code) involved in performing the inventive methods, such as the NSC polar codes decoder block 108 and the polar codes designer block 109. The skilled reader will readily understand that actions related to decoding may be encompassed in block 108 and actions related to polar code design may be encompassed in block 109. In practice, however, these blocks are not necessarily embodied in separate computer programs or separate circuitry in an IC; they could be embodied in the same computer program or the same circuitry, if so chosen.

The present technique provides an advantageous methodology for data-driven polar decoders. The methodology treats the channel as a “black box” used to generate samples of input-output pairs without access to the channel's explicit model. It dissects the polar decoder into two separate components. The first is the sufficient statistic of the channel outputs, that is denoted here by E (note that, when the polar decoder is used for data decompression, the statistic is of input data). The function E: [symbol] →ε embeds the channel outputs into a latent space ε⊂ [symbol] ^{d}. The embeddings e∈ε are then used as the inputs of the second component—three artificial neural networks (ANNs, or NNs for short) that replace the three core elements of the traditional SC decoder: the check-node, the bit-node, and the soft-decision operations.

The present technique may be divided into two phases: a training phase and an inference phase. In a training phase, the parameters of the embedding function E (the channel's output statistics), the check-node, the bit-node, and the soft-decision operations are determined by estimating the mutual information (MI) of the synthesized channels

$${W}_{N}^{( i )} .$$

The training may be performed in two alternative ways. The first trains the embedding and the three other ANNs jointly. The second determines the parameters of the embedding E using neural estimation methods (such as, for example, those of D. Tsur, Z. Aharoni, Z. Goldfeld, and H. Permuter, “Neural Estimation and Optimization of Directed Information Over Continuous Spaces,” IEEE Trans. Inf. Theory, Volume 69, Issue 8, August 2023; D. Tsur, Z. Aharoni, Z. Goldfeld, and H. Permuter, “Data-Driven Optimization of Directed Information Over Discrete Alphabets,” IEEE Trans. Inf. Theory, Volume 70, Issue 3, March 2024; or Z. Aharoni, D. Tsur, and H. H. Permuter, “Density Estimation of Processes with Memory via Donsker Varadhan,” in 2022 IEEE Int. Symp. Inf. Theory (ISIT), 2022), and then determines the parameters of the three other ANNs while the parameters of E are fixed. At the end of the training phase, the set of “clean” synthesized channels are determined by a Monte-Carlo (MC) evaluation of the MI of the synthesized channels to complete the polar code design. During the inference phase, the “frozen set” of the polar code design, as well as the parameters of the embedding function and the NSC, are fixed. With its parameters fixed, the NSC decoder may be utilized for decoding.

The NSC decoder is a consistent estimator of an analytic polar decoder. Specifically, for FSC, the NSC decoder provides a consistent estimator of the mutual information of the synthesized channels. Also disclosed here is the computational complexity of the NSC decoder, which, advantageously, does not grow with the channel memory. Specifically, the NSC has a decoding computational complexity of O(md N log N), where d is the dimension of the channel embeddings and m are the number of hidden units of the realized neural network. This is a main advantage over the traditional SCT decoder whose computational complexity grows cubicly with the channel memory size.

Also disclosed here is an extension of the NSC for input distribution with memory. This involves using the Honda-Yamamoto scheme (see J. Honda and H. Yamamoto, “Polar Coding without Alphabet Extension for Asymmetric Models,” IEEE Trans. Inf. Theory, vol. 59, no. 12, pp. 7829-7838, 2013).

The present technique is supported by empirical evidence, encompassing both memory and memoryless channels. The experiments discussed below validate the effectiveness of the present technique against the ground truth, i.e., the optimal performance achievable by a SC decoding scheme with complete knowledge of the channel model. Additionally, the experiments highlight the present technique's scalability, showcasing results for large block lengths (up to 2¹⁰).

### Notations and Preliminaries

Throughout this disclosure, the underlying probability space upon which all random variables are defined is denoted by (Ω, [symbol] , [symbol] ). Here, Ω is the set of all two-sided infinite sequences of real numbers, represented by ω=( . . . , ω₋₁, ω₀, ω₁, . . . ), with each ωᵢ∈ [symbol] for every integer i. The symbol [symbol] denotes the corresponding Borel σ-algebra, ensuring that events involving these sequences are well-defined and measurable. The probability measure, denoted by [symbol] , is chosen to be the Lebesgue measure, which facilitates the assignment of probabilities to events within [symbol] . Lastly, [symbol] denotes the expectation operator, used to calculate the expected value of random variables defined over this probability space. Random variables (RVs) are denoted by capital letters and their realizations by lower-case letters, e.g. X and x, respectively. Calligraphic letters denote sets, e.g. χ. The notation

$${X}_{i}^{j}$$

is used to denote the RV (Xᵢ, Xᵢ₊₁, . . . , Xⱼ) and

$${x}_{j}^{i}$$

to denote its realization for i<j. If i=1, the index i may be omitted to simplify notation, i.e., the notation X^{j} may be used instead. The probability Pr[X=x] is denoted by P_{X}(x). Stochastic processes are denoted by blackboard bold letters, e.g., [symbol] :=(Xᵢ) [symbol] . An n-coordinate projection of [symbol] is denoted by P_{X}_{ⁿ}_{Y}_{ⁿ}= [symbol] |_{σ(X}_{ⁿ}_{,Y}_{ⁿ}₎, where σ(Xⁿ, Yⁿ) is the σ-algebra generated by (Xⁿ, Yⁿ). [N] denotes the set of integers {1, . . . , N}.

The MI between two RVs X, Y is denoted by I(X; Y). The directed information (DI) between Xⁿ and Yⁿ is defined as

$$I ( {X}^{n} \to {Y}^{n} ) = {\sum }_{i = 1}^{n} I ( {X}^{i} ; {Y}_{i} \vert {Y}^{i - 1} ) .$$

For two distributions P, Q, the cross entropy (CE) is denoted by h_{CE}(P, Q), the entropy is denoted by H(P) and the Kullback-Leibler (KL) divergence is denoted by D_{KL}(P∥Q). The notation P<<Q indicates that P is absolutely continuous with respect to Q.

The tuple (W_{Y|X}, χ, [symbol] ) defines a memoryless channel with input alphabet χ, output alphabet [symbol] and a transition kernel W_{Y|X}. Throughout the disclosure it is assumed that χ={0,1}. For a memoryless channel, its input distribution is denoted by P_{X}=P_{X}_{ᵢ} for all i∈

[symbol]

The tuple (W_{Y∥X}, χ, [symbol] ) defines a time-invariant channel with memory, where

$${W}_{Y \vert \vert X} = {\{ {W}_{{Y}_{0} \vert {Y}_{- i + 1}^{- 1} , {X}_{- i + 1}^{0}} \}}_{i ∈ ℕ} , and {X}_{- i}^{0} = [ {X}_{- i} , {X}_{- i + 1} , … , {X}_{- 1} , {X}_{0} ] .$$

The term

$${W}_{{Y}^{N} \vert \vert {X}^{N}} = {\prod }_{i = 1}^{N} {W}_{{Y}_{0} \vert {Y}_{- i + 1}^{- 1} , {X}_{- i + 1}^{0}}$$

denotes the probability of observing Y^{N} causally conditioned on X^{N} The symmetric capacity of a channel is denoted by I(W). The term [symbol] _{M,N}={x_{j,i}, y_{j,i}}_{j∈[M],i∈[N]}˜P_{X}_{^{MN}}⊗W_{Y}_{^{MN}}_{∥X}_{^{MN}} denotes a finite sample of input-output pairs of M consecutive blocks of N symbols, where x_{j,i}, y_{j,i} denotes the i-th input and output of the j-th block. The notation

$${x}_{j , 1}^{N}$$

denotes the collection

$${\{ {x}_{j , i} \}}_{i = 1}^{N} .$$

The term [symbol] _{MN}={xᵢ, yᵢ}_{i∈[MN]} denotes the same sample as [symbol] _{M,N} after its concatenation into one long sequence of inputs and outputs pairs.

A DFC is defined by the tuple (χ, [symbol] P_{S′,Y|X,S}), where X is the channel input, Y is the channel output, S is the channel state at the beginning of the transmission, and S′ is the channel state at the end of the transmission. The cardinalities χ, [symbol] are assumed to be finite. At each time t, the channel has the Markov property, that is, P_{S}_{ₜ}_{,Y}_{ₜ}_{|X}_{^{t}}_{,S}_{^{t-1}}_{,Y}_{^{t-1}}=P_{Y}_{ₜ}_{,S}_{ₜ}_{|X}_{ₜ}_{,S}_{ₜ₋₁}. A FSC is called indecomposable if for every ε>0 there exists an t₀∈ [symbol] such that for t≥t₀ we have

$$sup \vert {P}_{{S}_{t} \vert {X}^{t} , {S}_{0}} ( {s}_{t} \vert {x}^{t} , {s}_{0} ) - {P}_{{S}_{t} \vert {X}^{t} , {S}_{0}} ( {s}_{t} \vert {x}^{t} , {s}_{0}^{′} ) \vert < ε .$$

In the context of polar codes for symmetric channels, let G_{N}=B_{N}F^{⊗n} represent the generator matrix for a block length of N=2ⁿ, where n∈ [symbol] , defining what is known as Arikan's polar transform. The matrix B_{N} is the permutation matrix associated with the bit-reversal permutation. It is defined by the recursive relation

$${B}_{N} = {R}_{N} ( {I}_{2} ⊗ {B}_{\frac{N}{2}} )$$

starting from B₂=I₂. The term I_{N} denotes the identity matrix of size N, and R_{N} denotes a permutation matrix called reverse-shuffle by Arikan. The matrix G_{N} satisfies G_{N}G_{N}=I_{N}. The term A⊗B denotes the Kronecker product of A and B when A, B are matrices, and it denotes a tensor product whenever A, B are distributions. The term A^{⊗N}:=A⊗A⊗ . . . ⊗A denotes an application of the ⊗ operator N times.

A polar code is defined herein by the tuple (χ, [symbol] , W, E^{W}, F, G, H) that contains the channel W, the channel embedding E^{W} and the core components of the SC decoder, F, G, H. The synthesized channels are defined by the tuple

$$( {W}_{N}^{( i )} , 𝒳 , {𝒳}^{i - 1} \times )$$

for all i∈[N]. The term E^{W}: [symbol] →ε denotes the channel embedding (also referred to in the literature as “channel statistics”), where ε⊂ [symbol] ^{d}. For example, for a memoryless channel W:=W_{Y|X}, a valid choice of E^{W}, as used in the remainder of this disclosure, is given by the following:

$${E}^{W} ( y ) = log \frac{w ( y \vert 1 )}{w ( y \vert 0 )} + log \frac{{P}_{X} ( 1 )}{{P}_{X} ( 0 )} , \qquad ( 1 )$$

where the second term in the right-hand-side (RHS) cancels out in the case where P_{X} is uniform.

The functions F: ε×ε→ε, G: ε×ε×χ→ε denote the check-node and bit-node operations, respectively. H: ε→[0,1] denotes a mapping of the embedding into a probability value, i.e., a soft-decision. For memoryless channels and with the selection of E^{W} as defined in Equation (1), the functions F, G, and H are specified as follows:

$$F ( {e}_{i} , {e}_{2} ) = 2 {tanh}^{- 1} ( tanh \frac{{e}_{1}}{2} tanh \frac{{e}_{2}}{2} ) , \qquad ( 2 )$$

$$G ( {e}_{1} , {e}_{2} , u ) = {e}_{2} + {( - 1 )}^{u} {e}_{1} , H ( {e}_{1} ) = σ ( {e}_{1} ) ,$$

where

$$σ ( x ) = \frac{1}{1 + {e}^{- x}}$$

is the logistic function and e₁, e₂∈ [symbol] , u∈χ. For this choice, the hard decision rule h: [0,1]→χ is the round function h(l)= [symbol] _{l>0.5}, where [symbol] is the indicator function. Applying SC decoding on the channel outputs yields an estimate of the transmitted bits and their corresponding posterior distribution. Specifically, after observing

$${y}_{1}^{N} ,$$

SC decoding performs the map

$$( {y}_{i}^{N} , {f}_{1}^{N} ) ↦ {\{ {\hat{u}}_{i} , {P}_{{U}_{i} \vert {U}_{1}^{i - 1} , {Y}_{1}^{N}} ( 1 \vert {\hat{u}}_{1}^{i - 1} , {y}_{1}^{N} ) \}}_{i ∈ [ N ]} .$$

The term

$${f}_{1}^{N}$$

represents the common information between the encoder and the decoder by setting

$${f}_{i} = \{ \begin{matrix}{u}_{i} & i {∈}^{c} \\ 0.2 & i ∈\end{matrix} ,$$

where the value 0.5 is chosen arbitrarily to indicate that the bit needs to be decoded, the set [symbol] ⊆[N] is the information set, and [symbol] =[N]\ [symbol] is the frozen set. This mapping is denoted by

$${\{ {\hat{u}}_{i} , {P}_{{U}_{i} \vert {U}_{1}^{i - 1} , {Y}_{1}^{N}} ( 1 \vert {\hat{u}}_{1}^{i - 1} , {y}_{1}^{N} ) \}}_{i ∈ [ N ]} = {SC}_{decode} ( {y}_{1}^{N} , {f}_{1}^{N} ) . \qquad ( 3 )$$

For the case where the input distribution is uniform and independent and identically distributed (i.i.d.),

$$𝒜 = {SC}_{design} ( {𝒟}_{M , N} , k , {E}^{W} , F , G , H )$$

denotes a procedure for finding the set of good channels [symbol] ⊂[N] with | [symbol] =k over the sample [symbol] _{M,N} with a SC decoder that uses E^{W}, F, G, H as its elementary operations. This amounts to applying SC_{decode} on the M blocks id [symbol] _{M,N}. In the design phase, it is assumed that both

$${u}_{1}^{n} and {y}_{1}^{n}$$

are known to the decoder, and therefore

$${f}_{1}^{N} = {u}_{1}^{N}$$

in the design phase (all bits are frozen). Each application of SC decoding yields in

$${\{ {P}_{{U}_{i} \vert {U}^{i - 1} , {Y}^{N}} ( 1 \vert {u}_{j , 1}^{i - 1} , {y}_{j , 1}^{N} ) \}}_{j ∈ [ M ] , i ∈ [ N ]}$$

Note that the conditioning is over the true bits

$${u}_{j , 1}^{N} .$$

For each i∈[N], the empirical average

$$\hat{I} ( {W}_{N}^{( i )} ) = 1 + \frac{1}{M} {\sum }_{j = 1}^{M} log {P}_{{U}_{i} \vert {U}_{1}^{i - 1} , {Y}_{1}^{N}} ( {u}_{j , 1} \vert {u}_{j , 1}^{i - 1} , {y}_{j , 1}^{N} ) \qquad ( 4 )$$

is computed to estimate the MI of the synthesized channels. Note that Equation (4) follows due to the fact that

$$H ( {U}_{i} \vert {U}_{1}^{i - 1} ) = 1$$

and the second term is an estimate of

$$H ( {U}_{i} \vert {U}_{1}^{i - 1} {Y}_{1}^{N} )$$

by the law of large numbers. This estimate is used to complete the polar code design by choosing [symbol] ⊂[N] with the highest values of

$${\{ \hat{I} ( {W}_{N}^{( i )} ) \}}_{i ∈ [ N ]} .$$

The class of shallow NNs, i.e., NNs with one hidden layer and with fixed input and output dimensions, is defined as follows:

Definition 1 (NN function class): For the ReLU activation function σ_{R}(x)=max(x, 0) and dᵢ, dₒ∈ [symbol] , define the class of neural networks with k∈ [symbol] neurons as:

$${𝒢}_{NN}^{( {d}_{i} , k , {d}_{o} )} := \{ g : {ℝ}^{{d}_{i}} \to {ℝ}^{{d}_{o}} : g ( x ) = {\sum }_{j = 1}^{k} {β}_{j} {σ}_{R} ( {W}_{j} x + {b}_{j} ) , x ∈ {ℝ}^{{d}_{i}} \} , \qquad ( 5 )$$

where σ_{R} acts component-wise, βⱼ∈ [symbol] , Wⱼ∈ [symbol] ^{d}^{ₒ}^{×d}^{ᵢ} and bⱼ∈ [symbol] ^{d}^{ₒ} are the parameters of

$$g ∈ {𝒢}_{NN}^{( {d}_{i} , k , {d}_{o} )} .$$

Then, the class of NNs with input and output dimensions (dᵢ, dₒ) is given by

$${𝒢}_{NN}^{( {d}_{i} , {d}_{o} )} := {⋃}_{k ∈ ℕ} {𝒢}_{NN}^{( {d}_{i} , k , {d}_{o} )} , \qquad ( 6 )$$

and the class of NNs is given by

$${𝒢}_{NN} := {⋃}_{{d}_{i} , {d}_{o} ∈ ℕ} {𝒢}_{NN}^{( {d}_{i} , {d}_{o} )} .$$

NNs form a universal approximation class under mild smoothness conditions. The following theorem specifies the conditions for which NNs are universal approximators.

Theorem 1 (Universal approximation of NNs): Let C(χ, [symbol] ) be the class of continuous functions f: χ→ [symbol] where χ⊂ [symbol] ^{d}^{ᵢ} is compact and [symbol] ⊆ [symbol] ^{d}^{ₒ}. Then, the class of

$$NNs {𝒢}_{NN}^{( {d}_{i} , {d}_{o} )}$$

is dense in C(χ, [symbol] ), i.e., for every f∈C(χ, [symbol] ) and ε>0, there exist

$$g ∈ {𝒢}_{NN}^{( {d}_{i} , {d}_{o} )}$$

such that ∥ƒf-g∥_{∞}≤ϵ.

### Data-Driven Polar Codes for Memoryless Channels

This section focuses on designing data-driven polar codes for memoryless channels.

Let W:=W_{Y|X} be a binary-input memoryless channel. Consider [symbol] _{MN}˜(P_{X}⊗W_{Y|X})^{⊗MN} as a finite sample of its input-output pairs, with P_{X}(0)=P_{X}(1)=0.5. The SC decoding algorithm transforms the channel embedding, as detailed in Equation (1), into the synthesized channels embedding using recursive formulas from Arikan, Prop. 3. Notably, while the SC decoder necessitates the explicit channel embedding E^{W}, the channel transition kernel remains unknown in data-driven scenarios. To tackle this challenge, the mutual information neural estimator (MINE) algorithm may be used to estimate the channel embedding function (see M. I. Belghazi, A. Baratin, S. Rajeswar, et al., “MINE: Mutual Information Neural Estimation,” arXiv:1801.04062, 2018). Given [symbol] _{MN}, the MINE algorithm approximates I(X; Y) using the Donsker Varadhan (DV) variational formula for KL divergences (see M. D. Donsker and S. S. Varadhan, “Asymptotic Evaluation of Certain Markov Process Expectations for Large Time. IV,” Communications on Pure and Applied Mathematics, vol. 36, no. 2, pp. 183-212, 1983). This approximation results in an estimation of the symmetric capacity (owing to the uniformity of P_{X}) as

$${I}_{Φ} ( {𝒟}_{MN} ) = {max}_{ϕ ∈ Φ} \frac{1}{MN} {\sum }_{i = 1}^{MN} {T}_{ϕ} ( {x}_{i} , {y}_{i} ) - log \frac{1}{MN} {\sum }_{i = 1}^{MN} {e}^{{T}_{ϕ} ( {x}_{i} , {\tilde{y}}_{i} )} , \qquad ( 7 )$$

where \tilde{y}ᵢ is obtained by shuffling {yᵢ}_{i∈[MN]}, T_{Φ} is the estimated maximizer from the DV formula, and Φ is a compact parameter space for the NN. The MINE algorithm is represented as T_{Φ}=MINE( [symbol] _{MN}).

The optimal solution of the DV formula is given by

$${T}^{*} ( x , y ) = log \frac{W ( y \vert x )}{\frac{1}{2} W ( y \vert 0 ) + \frac{1}{2} W ( y \vert 1 )} + c$$

for c∈ [symbol] . This connects T* and E^{W} through the relation E^{W}(y)=T*(1, y)−T*(0, y). Therefore, when the statistics of the channel are not known, the MINE algorithm's output is used as a proxy for E^{W}(y) by

$${E}_{Φ}^{W} y = {T}_{Φ} 1 , y - {T}_{Φ} 0 , y \qquad ( 8 )$$

This process is outlined in Algorithm 1.

Algorithm 1: Data-driven polar code for memoryless channels
input: Dataset [symbol] _{M,N}, # of iterations Nᵢₜₑᵣₛ, # of information bits k
output: Clean set [symbol]
T_{φ} = MINE( [symbol] _{MN})
${E}_{Φ}^{W} = {T}_{Φ} ( 1 , \cdot ) - {T}_{Φ} ( 0 , \cdot )$
$𝒜 = {SC}_{design} ( {𝒟}_{M , N} , k , {E}_{Φ}^{W} , F , G , σ ) .$

The following theorem states that Algorithm 1 induces a consistent estimate of

$$H ( {U}_{i} \vert {U}_{1}^{i - 1} , {Y}_{1}^{N} )$$

for memoryless channels.

Theorem 2 (Successive Cancellation Decoding with MINE for Memoryless Channels): Let [symbol] _{MN}˜(P_{X}⊗W_{Y|X})^{⊗MN} where N=2ⁿ, M, n∈ [symbol] . Let

$${u}_{j , i} = {( {x}_{j , 1}^{N} {G}_{N} )}_{i} .$$

### Let

$${E}_{Φ}^{W}$$

as defined in Equation (8). Then, for every ε>0 there exists p∈ [symbol] , compact Φ⊂ [symbol] ^{p} and m∈ [symbol] such that for M>m and i∈[N],—a.s.

$$\vert {H}_{Φ}^{M} ( {U}_{i} \vert {U}_{1}^{i - 1} , {Y}_{1}^{N} ) - H ( {U}_{i} \vert {U}_{1}^{i - 1} , {Y}_{1}^{N} ) \vert < ε , \qquad ( 9 )$$

$$where$$

$${H}_{Φ}^{M} ( {U}_{i} \vert {U}_{1}^{i - 1} , {Y}_{1}^{N} ) = - \frac{1}{M} {\sum }_{j = 1}^{M} log {P}_{{U}_{i} \vert {U}_{1}^{i - 1} , {Y}_{1}^{N}}^{Φ} ( {u}_{j , i} \vert {u}_{j , 1}^{i - 1} , {y}_{j , 1}^{N} ) , \qquad ( 10 )$$

and

$${P}_{{U}_{i} \vert {U}_{1}^{i - 1} , {Y}_{1}^{N}}^{Φ} ( {u}_{j , i} \vert {u}_{j , 1}^{i - 1} , {y}_{j , 1}^{N} )$$

is obtained by applying SC decoding (using F, G, H as defined in Equation (2)) with inputs

$${\{ {E}_{Φ}^{W} ( {y}_{j , i} ) \}}_{i = 1}^{N}$$

instead of

$${\{ {E}^{W} ( {y}_{j , i} ) \}}_{i = 1}^{N} .$$

Theorem 2 has been proven by the inventors, and its proof follows by two arguments. The first is the consistency of the MINE algorithm. The second exploits the continuity of the SC decoder to deduce the consistency of

$${H}_{Φ}^{M} ( {U}_{i} \vert {U}_{1}^{i - 1} , {Y}_{1}^{N} ) .$$

It should be noted that the condition stated in Equation (9) is sufficient to ensure that Algorithm 1 produces a polar code such that for any N=2ⁿ, n∈ [symbol] there exists M∈ [symbol] for which the block error rate is O(2^{N-}^{^{β}}) where

$$β < \frac{1}{2} ,$$

as the analytic polar code in E. Arikan and E. Telatar, “On the Rate of Channel Polarization,” in 2009 IEEE International Symposium on Information Theory, IEEE, pp. 1493-1495, 2009. The law of the large numbers implies that

$${lim}_{M \to {∞}_{Φ}}^{M} {U}_{i} \vert {U}_{1}^{i - 1} , {Y}_{1}^{N} = {P}_{{U}_{i} \vert {U}_{1}^{i - 1} , {Y}_{1}^{N}} {P}_{{U}_{i} \vert {U}_{1}^{i - 1} , {Y}_{1}^{N}}^{Φ} .$$

This is equivalent to

$${lim}_{M \to ∞} {H}_{Φ}^{M} ( {U}_{i} \vert {U}_{1}^{i - 1} , {Y}_{1}^{N} ) - H ( {U}_{i} \vert {U}_{1}^{i - 1} , {Y}_{1}^{N} ) = {D}_{K L} ( {P}_{{U}_{i} \vert {U}_{1}^{i - 1} , {Y}_{1}^{N}} ‖ {P}_{{U}_{i} \vert {U}_{1}^{i - 1} , {Y}_{1}^{N}}^{Φ} \vert {P}_{{U}_{1}^{i - 1} , {Y}_{1}^{N}} ) .$$

Theorem 2 suggests that

$${lim}_{M \to ∞} {D}_{K L} ( {P}_{{U}_{i} \vert {U}_{1}^{i - 1} , {Y}_{1}^{N}} ‖ {P}_{{U}_{i} \vert {U}_{1}^{i - 1} , {Y}_{1}^{N}}^{Φ} \vert {P}_{{U}_{1}^{i - 1} , {Y}_{1}^{N}} ) = 0$$

which implies that

$${P}_{{U}_{i} \vert {U}_{1}^{i - 1} , {Y}_{1}^{N}} and {P}_{{U}_{i} \vert {U}_{1}^{i - 1} , {Y}_{1}^{N}}^{Φ}$$

are equal almost everywhere. Thus, their corresponding Bhattacharyya parameters are equal and consequently have the same block error rate.

### Data-Driven Polar Codes for Channels with Memory

This section presents the data-driven methodology for the estimation of a neural polar decoder for channels with memory. In this case, both the channel embedding and the other three NNs that make up the polar decoder need to be estimated. The section starts with the NSC decoder's definition, and then presents an algorithm that optimizes these three NNs and the channel embedding jointly. Next, it presents neural estimation methods that allow the estimation of the channel embedding independently from the NSC decoder.

The following definition defines the NSC decoder on the basis of Arikan's SC decoder. Specifically, it uses the structure of the SC decoder and replaces its elementary operations by NNs. To simplify the following discussion, the definition below refers only to the three elementary operations of the SC decoder (and the NSC decoder, correspondingly), but in practice, the NSC decoder is made up also of a channel embedding NN.

Definition 2 (Neural Successive Cancellation Decoder): Let

$${E}_{ϕ}^{W} 𝒢 {∈}_{N N}$$

be a channel embedding with a compact parameter space Φ⊂ [symbol] ^{p}, p∈ [symbol] , satisfying

$${E}_{ϕ}^{W} : 𝒴 \to ε ,$$

$$ε ⊂ {ℝ}^{d} .$$

A NSC is defined by F_{θ}_{₁}, G_{θ}_{₂}, H_{θ}_{₃}∈ [symbol] _{NN} with parameters θ={θ₁, θ₂, θ₃} in a compact Θ⊂ [symbol] ^{p}, p∈ [symbol] . The NNs satisfy:
F_{θ}: ε×ε→ε is the check-node NN.
G_{θ}: ε×ε×χ→ε is the bit-node NN.
H_{θ}: ε→[0,1] is the soft-decision NN.

Application of SC decoding, as defined in Equation (3), with the functions

$${E}_{ϕ}^{W} ,$$

F_{θ}, G_{θ}, H_{θ} (instead of E^{W}, F, G, H as defined in Equations (1) and (2)) yields

$${P}_{{U}_{i} \vert {U}_{1}^{i - 1} , {Y}_{1}^{N}}^{ϕ , θ} ,$$

that is an estimate of

$${P}_{{U}_{i} \vert {U}_{1}^{i - 1} , {Y}_{1}^{N}} .$$

### Let

$${H}_{ϕ , θ} ( {U}_{i} \vert {U}_{1}^{i - 1} , {Y}_{1}^{N} ) = {h}_{C E} ( {P}_{{U}_{i} \vert {U}_{1}^{i - 1} , {Y}_{1}^{N}} , {P}_{{U}_{i} \vert {U}_{1}^{i - 1} , {Y}_{1}^{N}}^{ϕ , θ} ) \qquad ( 11 )$$

be the CE between

$${P}_{{U}_{i} \vert {U}_{1}^{i - 1} , {Y}_{1}^{N}} and {P}_{{U}_{i} \vert {U}_{1}^{i - 1} , {Y}_{1}^{N}}^{ϕ , θ} .$$

The training of the parameters of the NSC is now discussed. Training the NSC amounts into optimizing φ, θ such that the symmetric capacities of the synthesized channels

$$I ( {W}_{N}^{( i )} )$$

are estimated. It follows that

$${W}_{N}^{( i )} = 1 - {U}_{i} \vert {U}_{1}^{i - 1} , {Y}_{1}^{N} , \qquad ( 12 )$$

due to

$$H ( {U}_{i} \vert {U}_{1}^{i - 1} ) = 1$$

since

$${U}_{i} {∼}^{iid} Ber ( 0.5 ) ,$$

Hence, the goal of estimating

$${P}_{{U}_{i} \vert {U}_{1}^{i - 1} , {Y}_{1}^{N}}$$

set as the goal needed to identify the clean synthesized channels. This implies that minimizing CE between

$${P}_{{U}_{i} \vert {U}_{1}^{i - 1} , {Y}_{1}^{N}} and {P}_{{U}_{i} \vert {U}_{1}^{i - 1} , {Y}_{1}^{N}}^{ϕ , θ}$$

is a valid objective for the optimization of φ, θ. However, in the data-driven scenario, the true distribution

$${P}_{{U}_{i} \vert {U}_{1}^{i - 1} , {Y}_{1}^{N}}$$

is not known, and thus the CE is approximated by the negative-log-loss, which is calculated solely based on

$${P}_{{U}_{i} \vert {U}_{1}^{i - 1} , {Y}_{1}^{N}}^{ϕ , θ} .$$

That is, the negative log-loss employs an explicit model of

$${P}_{{U}_{i} \vert {U}_{1}^{i - 1} , {Y}_{1}^{N}}^{ϕ , θ} ,$$

relying only on samples (and not on the explicit model itself) drawn from

$${P}_{{U}_{i} \vert {U}_{1}^{i - 1} , {Y}_{1}^{N}} .$$

The following definition presents the objective for the optimization of the NSC parameters θ and the channel embedding E_{φ}.

Definition 3 (Optimization Objective of the NSC): Let [symbol] _{M,N}˜P_{X}_{^{MN}}⊗W_{Y}_{^{MN}}_{∥X}_{^{MN}}, where N is the block length and M∈ [symbol] is the number of blocks. Let

$${u}_{j , i} = {( {x}_{j , 1}^{N} {G}_{N} )}_{i}$$

and let for all i∈[N]

$${H}_{ϕ , θ}^{M} ( {U}_{i} \vert {U}_{1}^{i - 1} , {Y}_{1}^{N} ) = - \frac{1}{M} {\sum }_{j = 1}^{M} log {P}_{{U}_{i} \vert {U}_{1}^{i - 1} , {Y}_{1}^{N}}^{ϕ , θ} ( {u}_{j , i} \vert {u}_{j , 1}^{i - 1} , {y}_{j , 1}^{N} ) . \qquad ( 13 )$$

### Then,

$${min}_{θ ∈ Θ , ϕ ∈ Φ} \frac{1}{N} {\sum }_{i = 1}^{N} {H}_{ϕ , θ}^{M} U {(}_{i} \vert {U}_{1}^{i - 1} , {Y}_{1}^{N} ) \qquad ( 14 )$$

is the objective for training the NSC. Let

$${E}_{Φ}^{W} ,$$

F_{Θ}, G_{Θ}, H_{Θ} denote the NNs with parameters minimizing Equation (14) and

$${E}_{ϕ}^{W} ,$$

F_{θ}, G_{θ}, H_{θ} denote the NNs with parameters φ∈Φ, θ∈Θ. In the same manner, let

$${H}_{Φ , Θ}^{M} ( {U}_{i} \vert {U}_{1}^{i - 1} , {Y}_{1}^{N} )$$

denote the incurred loss for the i-th synthesized channel with parameters minimizing Equation (14).

The explicit computation of

$${P}_{{U}_{i} \vert {U}_{1}^{i - 1} , {Y}_{1}^{N}}^{ϕ , θ}$$

uses the recursive structure of the SC decoder. For each block j∈[M] in [symbol] _{M,N}, the channel inputs and outputs

$${x}_{j , 1}^{N} , {y}_{j , 1}^{N}$$

are selected and

$${u}_{j , 1}^{N}$$

is computed by

$${u}_{j , 1}^{N} = {x}_{j , 1}^{N} {G}_{N} .$$

For simplicity, the index of the block is neglected here, and focus is instead placed on a single block, i.e., the notation is simplified into

$${x}_{1}^{N} , {y}_{1}^{N} , {u}_{1}^{N} .$$

Let e_{l,i} denote the embedding of the i-th bit at the l-th decoding depth, and

$${e}_{l , 1}^{N}$$

denote all the embedding at the l-th decoding depth. E.g., e_{0,i} denotes the embedding of Xᵢ and e_{n,i} denotes the embedding of Uᵢ. Accordingly,

$${P}_{{U}_{i} \vert {U}_{1}^{i - 1} , {Y}_{1}}^{ϕ , θ} ( 1 \vert {u}_{1}^{i - 1} , {y}_{1}^{N} ) = {H}_{θ} ( {r}_{n , i} )$$

by applying the soft-decision NN. This is motivated since, by the structure of the SC decoder, e_{n,i} is a function of

$${u}_{1}^{i - 1} , {y}_{1}^{N} .$$

After observing

$${y}_{1}^{N} ,$$

the channel embeddings may be computed by

$${e}_{0 , i} = {E}_{ϕ}^{W} ( {y}_{i} ) .$$

In the next step, the frozen bits

$${f}_{1}^{N} = {u}_{1}^{N} and {e}_{0 , 1}^{N}$$

are used to compute the loss of the NSC, as appears in Definition 3. The loss computation may be performed by a recursive function that is based on the recursion of the SC decoder. The recursion starts with a loss accumulator initiated by L=0. Then, the NSC decoder starts the recursive computation of the synthesized channels, exactly as in SC decoding, until reaching the first leaf of the recursion. Upon reaching the first leaf, the first loss term of the NSC is accumulated into L. More specifically, a loss term

$${L}_{ce}^{θ} ( {e}_{n , 1} , {u}_{1} )$$

may be computed via the formula of the binary CE

$${L}_{ce}^{θ} ( e , u ) = - u log ( {H}_{θ} ( e ) ) - ( 1 - u ) log ( 1 - {H}_{θ} ( e ) ) . \qquad ( 15 )$$

That is the binary CE between

$${P}_{{U}_{1} \vert {Y}_{1}^{N}} ( \cdot \vert {y}_{1}^{N} ) and {P}_{{U}_{1} \vert {Y}_{1}^{N}}^{ϕ , θ} ( \cdot \vert {y}_{1}^{N} ) .$$

In the same manner, at each leaf of the recursion, additional loss term is accumulated to L. In particular, each time reaching a leaf, L may be updated according to the following rule

$$L = L + {L}_{ce}^{θ} ( {e}_{n , i} , {u}_{i} ) , i ∈ [ N ] . \qquad ( 16 )$$

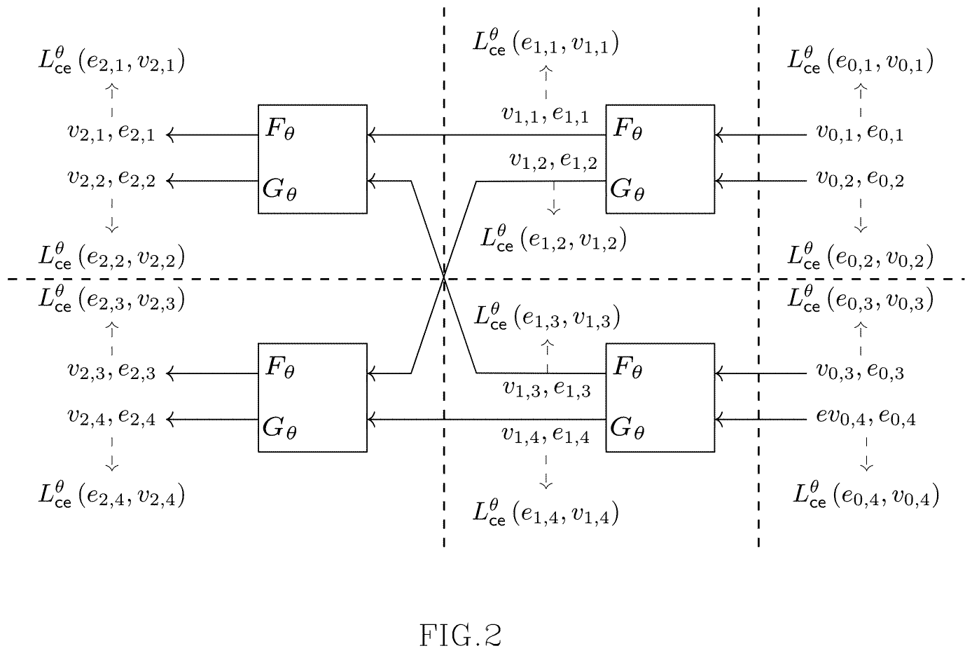

In addition, the algorithm may be made more rigid by accumulating the loss incurred by bits in intermediate decoding depths of 0, 1, . . . , n−1, i.e., the loss accumulates N(n+1) terms that correspond to all the bits in n+1 decoding depths, and for all N bits per each stage. Let v_{l,i} designate the i-th bit in l-th decoding depth of the recursion, as illustrated in FIG. 2. With this notation, the loss of the algorithm may be defined by

$$\begin{matrix}L = NSCLoss ( {e}_{0 , 1}^{N} , {u}_{1}^{N} , 0 ) \\ = \frac{1}{( n + 1 ) N} {\sum }_{l = 0}^{n} {\sum }_{i = 1}^{N} {L}_{ce}^{θ} ( {e}_{l , i} , {v}_{l , i} )\end{matrix} . \qquad ( 17 )$$

This is illustrated in FIG. 2 and Algorithm 2.

Algorithm 2: NSCLoss(e, u, L)

| N = dim (u) | |
|---|---|
| if N = 1 then | |
| $L = L + {L}_{ce}^{θ} ( e , u ) / / Loss at a leaf$ | |
| return L, u | |
| end if | |
| Split e into even and odd indices eₑ, eₒ | |
| e_{C} = F_{θ}(eₑ, eₒ) | //Check-node |
| $L , {v}_{1} = NSCLoss ( {e}_{C} , {u}_{1}^{N / 2} , L )$ | |
| e_{B} = G_{θ}(eₑ, eₒ, v₁) | //Bit-node |
| $L , {v}_{2} = NSCLoss ( {e}_{B} , {u}_{N / 2 + 1}^{N} , L )$ | |
| v = [v₁, v₂] | |
| v = v(I_{N/2} ⊗ G₂)R_{N} | //Bits in current depth |

$L = L + {\sum }_{i = 1}^{N} {L}_{ce}^{θ} ( {e}_{i} , {v}_{i} ) / / Loss in current depth$
return L, v

Algorithm 3: Data-driven polar decoder for channels with memory

```
input: Dataset [symbol]  _{M,N}, block length N, # of iterations Nᵢₜₑᵣₛ, # of information
bits k
output: Clean set [symbol]
  $Initialize the weights of {E}_{ϕ}^{W} , {F}_{θ} , {G}_{θ} , {H}_{θ}$
  for l = 1 to Nᵢₜₑᵣₛ do
    $Sample {x}_{1}^{N} , {y}_{1}^{N} ∼ {𝒟}_{M , N}$
    ${u}_{1}^{N} = {x}_{1}^{N} {G}_{N}$
    $Compute {e}_{0 , 1}^{N} by {e}_{0 , i} = {E}_{ϕ} {y}_{i}$
    $Compute L by applying NSCLoss ( {e}_{0 , 1}^{N} , {u}_{1}^{N} , 0 )$
    $Minimize L w . r . t {E}_{ϕ}^{W} , {F}_{θ} , {G}_{θ} , {H}_{θ}$
  end for
  $𝒜 = {SC}_{design} ( {𝒟}_{M , N} , k , {E}_{ϕ}^{W} , {F}_{θ} , {G}_{θ} , {H}_{θ} )$
  return [symbol]
```

The complete algorithm is given by the following steps, as given in Algorithm 3: First, the parameters of

$${E}_{ϕ}^{W} ,$$

F_{θ}, G_{θ}, H_{θ} are initialized randomly and the training block length is determined by N=2ⁿ^{ₜ}. Then, the algorithm proceeds to perform Nᵢₜₑᵣ iterations of training the NSC. Every iteration

$${x}_{1}^{N} , {y}_{1}^{N}$$

are drawn from [symbol] _{M,N}, and

$${u}_{1}^{N}$$

is computed by

$${u}_{1}^{N} = {x}_{1}^{N} {G}_{N} .$$

Next the channel embeddings are computed by e_{0,i}=E_{φ}(yᵢ) for all i∈[N]. At this stage the loss is computed by NSCLoss

$$( {e}_{0 , 1}^{N} , {u}_{1}^{N} , 0 ) ,$$

as given in Algorithm 2. The loss L is minimized using stochastic gradient descent (SGD) over the parameters φ, θ. This procedure repeats for a predetermined amount of steps, or until the CE stops improving.

Neural estimation methods for the estimation of the DI, such as those of Tsur 2023 and Tsur 2024 referenced above, may be adapted and used for the estimation of the channel embedding function independently from the NSC. The motivation for independent estimation of the channel embedding is demonstrated by memoryless channels. In this case, once the channel embedding is chosen, e.g., the log likelihood ratio (LLR), the corresponding SC decoder is compatible for all channels; the only thing that should be computed is the channel LLRs. Thus, above, the channel embeddings are estimated via the MINE algorithm, and the SC decoder is identical for all channels. In the same manner, it may be advantageous to provide an algorithm for the estimation of the channel embedding of channels with memory, such that it would be compatible with a single NSC decoder.

The following establishes that the directed information neural estimator (DINE) algorithm (discussed in Tsur 2023) can be adapted and utilized to create channel embeddings for channels with memory, analogous to how MINE is employed for memoryless channels. Furthermore, Tsur 2023 and Thur 2024 offer an algorithmic approach to estimate the capacity-achieving input distribution. Consequently, applying DINE yields an estimate of the input distribution as well as sufficient statistics of

$${Y}_{1}^{N} .$$

The DINE algorithm may be adapted for estimating the capacity of channels with memory. Let W:=W_{Y}_{^{MN}}_{∥X}_{^{MN}} be a binary-input channel with memory and let [symbol] _{MN}˜(P_{X}_{^{MN}}⊗W_{Y}_{^{N}}_{∥X}_{^{N}}) be a finite sample of its input-output pairs. The DINE algorithm may then estimate the DI rate from [symbol] to [symbol] using the following formula:

$${I}_{Ψ} ( 𝕏 \to 𝕐 ) = {max}_{ψ ∈ {Ψ}_{X Y}} \{ \frac{1}{M N} {\sum }_{i = 1}^{M N} {T}_{ψ} ( {y}_{i} ∣ {x}_{1}^{i} , {y}_{1}^{i − 1} ) − log \frac{1}{M N} {\sum }_{i = 1}^{M N} {e}^{T ( {ψ}_{i} {z}_{i} ∣ {x}_{1}^{i} , {y}_{1}^{i − 1} )} \} − {max}_{ψ ∈ {Ψ}_{Y}} \{ \frac{1}{M N} {\sum }_{i = 1}^{M N} {T}_{ψ} ( {y}_{i} ∣ {y}_{1}^{i − 1} ) − log \frac{1}{M N} {\sum }_{i = 1}^{M N} {e}^{{T}_{ψ} ( {z}_{i} ∣ {y}_{1}^{i − 1} )} \} , \qquad ( 18 )$$

where T_{ψ}∈ [symbol] _{RNN}, the space of recurrent neural networks (RNNs) whose parameter space is Ψ. The RVs

$${Z}_{1}^{N}$$

are auxiliary i.i.d. RVs distributed on [symbol] ^{N} and independent of

$${X}_{1}^{N} , {Y}_{1}^{N} .$$

The estimated maximizers of the first and second terms are denoted by T_{Ψ}_{_{XY}} and T_{Ψ}_{_{Y}}, respectively.

This DINE adaptation provides sufficient statistics of the channel outputs. The optimal maximizers of the i-th argument in first term in Equation (18) is given by

$${T}_{i}^{⋆} = log \frac{{P}_{{Y}_{i} ∣ {Y}_{1}^{i − 1} , {X}_{1}^{i}}}{{P}_{Z}} + c$$

for c∈ [symbol] and i∈ [symbol] . For fixed

$${y}_{1}^{N} ,$$

a new RV may be defined as

$${T}_{{y}_{i}}^{⋆} : {𝒳}_{1}^{i} \times {𝒴}_{1}^{i − 1} \to ℝ$$

by

$${T}_{{y}_{i}}^{⋆} ( {y}_{1}^{i} , {y}_{1}^{i - 1} ) = log \frac{{P}_{{Y}_{i} ∣ {Y}_{1}^{i − 1} , {X}_{1}^{i}} ( {y}_{i} ∣ {y}_{1}^{i − 1} , {x}_{1}^{i} )}{{P}_{Z} ( {y}_{i} )} . \qquad ( 19 )$$

The following states that

$${T}_{1}^{N} {=}^{Δ} {\{ {T}_{{Y}_{i}}^{⋆} \}}_{i = 1}^{N}$$

is a sufficient statistic of

$${Y}_{1}^{N}$$

for the estimation

$${U}_{1}^{N} .$$

Proposition 1: Let

$${X}_{1}^{N} , {Y}_{1}^{N} ∼ {P}_{{X}_{1}^{N}} ⊗ {W}_{{Y}_{1}^{N} \vert \vert {X}_{1}^{N}}$$

and P_{Z} such that P_{Y}<<P_{Z}. Then

$${T}_{1}^{N} ,$$

as defined in Equation (19), satisfies

$${U}_{1}^{N} - {Y}_{1}^{N} - {T}_{1}^{N} , \qquad ( 20 )$$

$${U}_{1}^{N} - {T}_{1}^{N} - {Y}_{1}^{N} , \qquad ( 21 )$$

where X-Y-Z designates a Markov relation between the RVs X, Y, Z.

Theorem 1 has been proven by the inventors, with the main steps being to express

$${P}_{{X}_{1}^{N} , {Y}_{1}^{N}}$$

in terms of

$${T}_{1}^{N}$$

and use the well-known Fisher-Neyman Factorization theorem.

Obtaining the parametric channel embedding from the adapted DINE model may be performed as follows. Theorem 1 suggests that DI estimation is an appropriate objective for the construction of the channel embedding of

$${Y}_{1}^{N}$$

needed for the NSC decoder. However, given

$${y}_{1}^{N} ,$$

the evaluation of

$${T}_{1}^{N}$$

for all

$${x}_{1}^{n} ∈ {𝒳}^{N}$$

involves an exponential number of computations. To overcome this, recall that according to Equation (18), T_{Ψ}_{_{XY}} is approximated by a RNN that contains a sequence of layers. Therefore, T_{ψ}_{_{XY}} can be broken down into two component functions. The first function is defined as

$${e}_{i} = {E}_{ϕ}^{W} ( {y}_{i} ) ,$$

and the second as

$${\tilde{T}}_{{ψ}_{XY}} ( {x}_{1}^{i} , {e}_{1}^{i} ) .$$

Together the compose T_{ψ}_{_{XY}} through the operation

$${T}_{{ψ}_{XY} , ϕ} ( {x}_{1}^{i} , {y}_{1}^{i} ) = {\tilde{T}}_{{ψ}_{XY}} ( {x}_{1}^{i} , {e}_{1}^{i} ) .$$

With this parameterization, after applying Algorithm 1, T_{Ψ}_{_{XY}}_{,Φ} is obtained, which contains

$${E}_{Φ}^{W}$$

as its intermediate layer. Since T_{Ψ}_{_{XY}}_{,Φ} is composed of sequential layers, any intermediate layer of T_{Ψ}_{_{XY}}_{,Φ} must preserve the information that flows to its outputs. Therefore,

$${E}_{Φ}^{W}$$

is chosen to be the channel embedding required for the NSC decoder. For this choice, the parameters of the channel embeddings are fixed and the NSC can be optimized without the optimization over Φ. Specifically, the minimization in Definition 3 is performed exclusively over Θ.

The next theorem shows the consistency of the NSC for channels with memory. It demonstrates that, for FSCs, Algorithm 3 yields a consistent estimator of the SC polar decoder.

Theorem 3 (Successive Cancellation Decoding of Time-Invariant Channels): Let [symbol] be the inputs and outputs of an indecomposable FSC as given above. Let

$${𝒟}_{M , N} \sim {P}_{{X}_{1}^{MN}} ⊗ {W}_{{Y}_{1}^{MN} \vert \vert {X}_{1}^{MN}} ,$$

where N=2ⁿ, M, n∈ [symbol] . Let

$${u}_{j , i} = {( {x}_{j , 1}^{N} {G}_{N} )}_{i} .$$

Then, for every ε>0 there exists p∈ [symbol] compact Φ, Θ∈ [symbol] ^{p} and m∈ [symbol] such that for M>m and i∈[N], [symbol] —a.s.

$$\vert {H}_{Φ , Θ}^{M} ( {U}_{i} \vert {U}_{1}^{i - 1} , {Y}_{1}^{N} ) - H ( {U}_{i} \vert {U}_{1}^{i - 1} , {Y}_{1}^{N} ) \vert < ε . \qquad ( 22 )$$

Theorem 3 concludes that there exist NNs that approximate the SC elementary operations with an arbitrary precision. It also indicates that these operations do not depend on the specific block, or the specific symbol location inside the block, i.e., the same NNs, E_{φ}, F_{θ}, G_{θ}, H_{θ}, may be used for all decoding stages and for all bits inside each decoding stage.

The proof has been obtained by the inventors. Briefly, it starts with identifying that the structure of

$${P}_{{U}_{i} ∣ {U}_{1}^{i − 1} , {Y}_{1}^{N}}^{ϕ , θ} ( 1 ∣ {u}_{1}^{i − 1} , {y}_{1}^{N} )$$

is induced by the structure of the SC decoder and that it contains 4 unique operations,

$${E}_{ϕ}^{W} ,$$

F_{θ}, G_{θ}, H_{θ}, that operate on channel embedding in [symbol] ^{d}. It continues with an approximation step, in which

$${P}_{{U}_{i} ∣ {U}_{1}^{i − 1} , {Y}_{1}^{N}} ( 1 ∣ {u}_{1}^{i − 1} , {y}_{1}^{N} )$$

is parameterized by a NN via the universal approximation theorem of NNs by Theorem₁. Then, an estimation step follows, in which expected values are estimated by empirical means via the uniform law of large numbers for stationary and ergodic processes.

The following theorem examines the computational complexity of the NSC decoder for the case where E_{φ}, F_{θ}, G_{θ}, H_{θ} are NNs with m hidden units and the embedding space satisfies ε⊂ [symbol] ^{d}.

Theorem 4 (Computational complexity of the NSC) Let

$${E}_{ϕ} ∈ {𝒢}_{NN}^{( 1 , m , d )} , {F}_{θ} ∈ {𝒢}_{NN}^{( 2 d , m , d )} , {G}_{θ} ∈ {𝒢}_{NN}^{( 2 d + 1 , m , d )} , {H}_{θ} ∈ {𝒢}_{NN}^{( d , m , 1 )} .$$

Then, the computational complexity of NSC decoding is O(mdN log₂ N).

The proof of Theorem 4 is as follows: According to Arikan, Section VIII, the recursive formulas of the SC decoder have complexity of O(N log N) and the decoding operations have complexity of O(1), and therefore the latter do not affect the overall complexity. Here, there are considered decoding operations that are given by NNs with input dimension at most 2d+1, m hidden units and output dimension of at most d. The complexity of such NN is O(md), that yields an overall complexity of the NSC to be O(mdN log N).

The only difference between Theorem 4 of this disclosure and Theorem 5 in Arikan is that the NN computation complexity is given explicitly by kd (even though it could have been neglected as it does not depend on N or the channel's state space). The goal of Theorem 4 is to compare the NSC decoder with SCT decoder. Recall that the computational complexity of the SCT decoder is O(| [symbol] |³N log N). This sets a main advantage of the present NSC decoder—its computational complexity does not grow with the memory size of the channel.

### Extension to Asymmetric Input Distributions Via Honda-Yamamoto Scheme

This section extends the present methods to accommodate asymmetric input distributions and input distributions with memory by incorporating the Honda-Yamamoto scheme (referenced above).

The Honda-Yamamoto scheme generalizes polar coding for asymmetric input distributions. Here, the polar decoder is applied twice: first, before observing the channel outputs and second, after observing the channel outputs. An equivalent interpretation is that the first application of SC decoding is done on a different channel whose outputs are independent of its inputs. Indeed, in this case, as given in Equation (1), the first term of the RHS cancels out, and it follows that the channel embeddings are constant for all y∈ [symbol] . Thus, for the first application of SC decoding, the constant input embedding is denoted by E^{X} (rather than E^{W}). The second application of SC decoding follows the same procedure as in the case of symmetric channels.

Accordingly, a polar decoder with asymmetric input distribution is defined by the tuple (χ, [symbol] , W, E^{X}, E^{W}, F, G, H). Here the input embedding E^{X} is added to the definition, where E_{X}(y) is constant for all y∈ [symbol] . An important observation is that the functions F, G, H are independent of the channel, i.e., both application of SC decoding (before and after observing the channel outputs) share the same functions F, G, H.

Given a finite sample [symbol] _{M,N},

$$𝒜 = {SC}_{design - HY} ( {𝒟}_{M , N} , k , {E}^{X} , {E}^{W} , F , G , H )$$

denotes the procedure of finding the set of good channels [symbol] ⊂[N] with | [symbol] |=k over the sample [symbol] _{M,N} with a SC decoder that uses E^{X}, E^{W}, F, G, H as its elementary operations. Specifically, for each block j∈[M], SC decoding is applied twice. First, E^{X} is used to compute the channel embedding; it yields in the computation of

$${\{ {P}_{{U}_{i} ∣ {U}_{1}^{i − 1}} ( 1 ∣ {u}_{j , 1}^{i − 1} ) \}}_{j ∈ [ M ] , i ∈ [ N ]} .$$

Next, E^{W} is used to compute the channel embedding; it yields in the computation of

$${\{ {P}_{{U}_{i} ∣ {U}_{1}^{i − 1} {Y}_{1}^{N}} ( 1 ∣ {u}_{j , 1}^{i − 1} {y}_{j , 1}^{N} ) \}}_{j ∈ [ M ] , i ∈ [ N ]} .$$

For each i∈[N], the empirical average

$$\hat{I} ( {W}_{N}^{( i )} ) = − \frac{1}{M} {\sum }_{j = 1}^{M} log {P}_{{U}_{i} ∣ {U}_{1}^{i − 1}} ( {u}_{j , i} ∣ {u}_{j , 1}^{i − 1} ) + \frac{1}{M} {\sum }_{j = 1}^{M} log {P}_{{U}_{i} ∣ {U}_{1}^{i − 1} , {Y}_{1}^{N}} ( {u}_{j , i} ∣ {u}_{j , 1}^{i − 1} , {y}_{j , 1}^{N} )$$

is computed to estimate the MI of the synthesized channels. This estimate is used to complete the polar code design by choosing [symbol] ⊂[N] with the highest values of

$${\hat{I} ( {W}_{N}^{( i )} )}_{i ∈ [ N ]} .$$

When considering memoryless channels, the case of asymmetric input distributions is similar to the case of polar code design for uniform input distributions. Non-uniform input distributions may be dealt with by applying the Honda-Yamamoto scheme. Consider W:=W_{Y|X} to be a binary-input memoryless channel and P_{X} an i.i.d. and non-uniform input distribution (in the case of memoryless channels it is sufficient to consider an iid input distribution since it achieves capacity). Accordingly, given [symbol] _{MN}, also here, once T_{Φ} is estimated via the MINE algorithm, it is used as a proxy of the channel embedding E^{W} by the formula

$${E}_{Φ}^{W} y = {T}_{Φ} ( 1 , y ) − {T}_{Φ} ( 0 , y ) + log \frac{{P}_{X} ( 1 )}{{P}_{X} ( 0 )} \qquad ( 23 )$$

and the Honda-Yamamoto scheme is applied “as-is.” Specifically, for this case, Algorithm 1 is applied with the only exception that the polar code design SC_{design} is replaced by SC_{design-HY}.

When channels with memory are concerned, two issues should be considered. The first is the choice of an input distribution. This is addressed by employing algorithms for capacity estimation, such as Tsur 2023 and Tsur 2024. The second issue addresses the construction of a NSC decoder that is tailored for input distributions with memory.

For the choice of the input distribution, the method for the optimization of the DINE, as presented in Tsur 2024, may be employed. Therein, a reinforcement learning (RL) algorithm is provided, that uses DINE to estimate capacity achieving input distributions. The input distribution is approximated with an RNN with parameter space denoted by Π. Let

$${P}_{X}^{π}$$

be the estimated capacity achieving input distribution. Thus, by application of Algorithm 1 in Tsur 2024, a model of

$${P}_{X}^{π}$$

is obtained, from which observations of the channel inputs can be sampled.

Extension of Algorithm 3 to P_{X}_{^{N}} (that is neither uniform nor i.i.d.) involves introducing additional parameters, denoted by φ₂∈Φ. Accordingly, the set of the channel embedding is denoted by φ={φ₁, φ₂}, where φ₁ denotes the parameters of E^{X} and φ₂ are the parameters of

$${E}^{W} \cdot {E}_{ϕ}^{X} : 𝒴 \to {ℝ}^{d}$$

is defined as a constant RV that satisfies

$${E}_{ϕ}^{W} ( y ) = {e}_{X} ∈ {ℝ}^{d}$$

for all y∈ [symbol] . Accordingly, the NSC in this case is defined by

$${E}_{ϕ}^{X} , {E}_{ϕ}^{W} ,$$

F_{θ}, G_{θ}, F_{θ}. Thus, Algorithm 3 needs to be updated in order to optimize

$${E}_{ϕ}^{X}$$

as well. This is addressed by first applying the NSC with inputs

$${e}_{X}^{N}$$

to compute

$${P}_{{U}_{i} \vert {U}_{1}^{i - 1}}^{ϕ , θ} ,$$

where

$${e}_{X}^{N} ∈ {ℝ}^{d \times N}$$

is a matrix whose columns are duplicates of e_{X}. Second, the NSC is applied with

$${e}_{Y}^{N}$$

to compute

$${P}_{{U}_{i} \vert {U}_{1}^{i - 1} , {Y}_{1}^{N}}^{ϕ , θ} ,$$

where

$${e}_{Y}^{N} ∈ {ℝ}^{d \times N}$$

is a matrix whose i-th column is

$${E}_{ϕ}^{W} ( {y}_{i} ) .$$

The training procedure admits the following steps. First, the channel inputs and outputs are sampled by

$${x}_{1}^{N} , {y}_{1}^{N} ∼ {P}_{{X}_{1}^{N}}^{π} ⊗ {W}_{{Y}_{1}^{N} \vert \vert {X}_{1}^{N}} .$$

Then, the values of

$${u}_{1}^{N} = {x}_{1}^{N} {G}_{N}$$

are computed, and form the labels of the algorithm. Next, the channel statistics

$${e}_{Y}^{N}$$

are computed and the input statistics are duplicated to obtain

$${e}_{X}^{N} .$$

The next step is to apply the NSC-Train procedure twice, i.e.,

$$X = NSCTrain ( {e}_{X}^{N} , {u}_{1}^{N} , 0 ) \qquad ( 24 )$$

$$Y = NS CTrain ( {e}_{Y}^{N} , {u}_{1}^{N} , 0 ) , \qquad ( 25 )$$

which are minimized via SGD. This procedure is illustrated in Algorithm 4.

Algorithm 4: Data-driven polar code design for channels with memory and
non-i.i.d. input distribution

```
input: Dataset [symbol]  _{M,N}, block length N, # of iterations Nᵢₜₑᵣₛ, # of information
bits k
output: Clean set [symbol]
  $Initiate the weights of {E}_{ϕ}^{X} , {E}_{ϕ}^{Y} and {G}_{θ} , {F}_{θ} , {H}_{θ}$
  for l = 1 to Nᵢₜₑᵣₛ do
    $Sample {x}_{1}^{N} , {y}_{1}^{N} ∼ {𝒟}_{M , N}$
    ${u}_{1}^{N} = {x}_{1}^{N} {G}_{N}$
  $Duplicate {e}_{X} to {e}_{X}^{N}$
  $Compute {e}_{Y}^{N} by {e}_{i} = E ( {y}_{i} )$
  $Compute {L}_{X} by applying NSCTrain ( {e}_{X}^{N} , {u}_{1}^{N} , 0 )$
  $Compute {L}_{Y} by applying NSCTrain ( {e}_{Y}^{N} , {u}_{1}^{N} , 0 )$
  Minimize _{X}+_{Y} w.r.t. φ,θ.
end for
$𝒜 = {SC}_{design} ( {𝒟}_{M , N} , k , {E}_{ϕ}^{X} , {E}_{ϕ}^{W} , {G}_{θ} , {F}_{θ} , {H}_{θ} )$
```

### List Decoding of Data-Driven Polar Codes

This section discusses the integration of list decoding for polar codes into the present technique, namely—data-driven polar codes. To this end, the NSC is benchmarked against two ground truth decoding methods: the SC decoder and the SCT decoder, depending on the presence or absence of channel memory. Notably, contemporary algorithms predominantly utilize the list decoding technique, known for its improved performance compared to the conventional SC algorithm. However, even greater performance may be achieved by incorporating list decoding with the NSC decoder, as discussed below.

To enhance the error correction performance of polar codes, especially with codes of moderate lengths, the SCL decoding algorithm was introduced in I. Tal and A. Vardy, “List Decoding of Polar Codes,” IEEE Trans. Inf. Theory, vol. 61, no. 5, pp. 2213-2226, 2015. The fundamental concept behind list decoding lies in leveraging the structured nature of the polar transformation. Instead of relying solely on a single SC decoder, the SCL decoder concurrently decodes multiple codeword candidates. This is achieved by applying multiple SC decoders over the same channel's outputs, with the number of these decoders denoted as the list size L.

The SCL decoder generates a list of potential codewords, each ranked by its likelihood of being the transmitted message. Subsequently, this list undergoes a refining process to identify the most likely original message. To achieve this, the SCL algorithm estimates each bit's value (0 or 1) while considering both possibilities. At each estimation step, the number of codeword candidates (also referred to as “paths”) doubles. To manage the algorithm's complexity, it employs a memory-saving strategy by retaining only a limited set of L codeword candidates at any given time. Consequently, after each estimation, half of the paths are discarded. To determine which paths to retain, a path metric (PM) is associated with each path. This metric is continuously updated with each new estimation and is computed via the LLRs. The algorithm maintains the L paths with the lowest path metrics, allowing them to persist and continue the decoding process.

List decoding can be integrated into the present data-driven polar codes, providing a NSC list decoder. Recall that the NSC decoder uses the same structure as the SC decoder and the SCT decoder, but replaces elementary operations with NNs. Since the NSC decoding algorithm can estimate the LLRs at the decision points, these can be leveraged to compute the PM and follow the same SCL decoding procedure.

As discussed above, the standard SC algorithm has a computational complexity of O(N log(N)), whereas the SCT algorithm's computational complexity is O(| [symbol] |³N log(N)). In the context of list decoding, Tal 2015 introduced a technique based on leveraging the memory sharing structure among the candidate paths. That technique demonstrated that the SCL decoder can be implemented with a computational complexity of O(LN log(N)). When applying the same technique to the SCT algorithm with list decoding, it follows directly that the computational complexity increases to O(L| [symbol] |³N log(N)).

The following theorem examines the computational complexity of the NSC list decoder for the case where E_{θ}, F_{θ}, G_{θ}, H_{θ} are NNs with k hidden units and the embedding space satisfies ε⊂ [symbol] ^{d}.

Theorem 5: Let E_{θ}, F_{θ}, G_{θ}, H_{θ} be NNs with k hidden units and let ε⊂ [symbol] ^{d}. Then, the computational complexity of NSC list decoding is O(LkdN log₂ N).

Theorem 5 has been proven by the inventors. Its main purpose is to facilitate a comparison between the NSC list decoder and SCT list decoder. Note that the computational complexity of the SCT list decoder, as previously mentioned, scales with the memory size of the channel O(L| [symbol] |³N log N). This highlights a key advantage of the NSC list decoder, since its computational complexity remains independent of the channel's memory size.

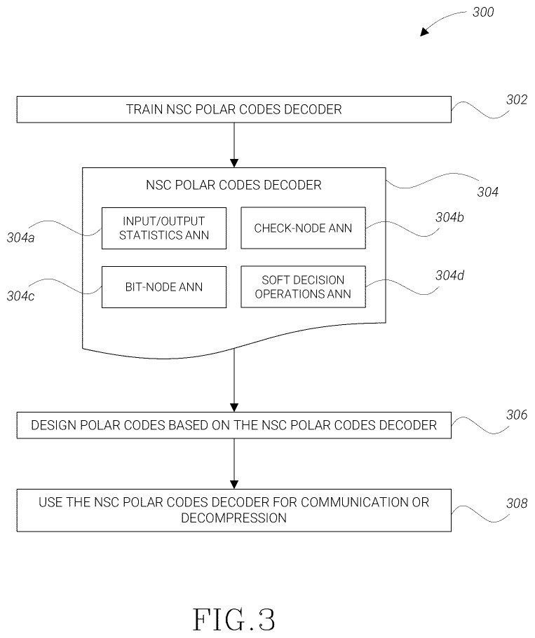

The instructions of blocks 108 and 109, which are apparent from the foregoing discussions, are now summarized and discussed with reference to the flowchart of FIG. 3, which illustrates a method 300 for using an NSC polar codes decoder for communication or decompression, in accordance with an embodiment. First, it should be noted that although the majority of the foregoing discussions pertain to a communication use case (in which the designed polar codes are used by an encoder to encode data before it is being transmitted over a communication channel, and then the NSC decoder is used at the receiver end of the channel to decode the data), this was merely done to simplify the discussions; the foregoing is equally applicable to a compression/decompression use case, with some elementary adaptations that will become apparent to those of skill in the art. Specifically, those of skilled in the art will recognize that error corrections codes, such as polar codes, are useful both for encoding and decoding of data in a data communications scenario and for compressing and decompressing data in order to reduce storage space or transmission bandwidth. Therefore, method 300, much like the foregoing discussions, is applicable to both use cases—communication and compression/decompression.

Steps of method 300 may either be performed in the order they are presented or in a different order (or even in parallel), as briefly mentioned above, as long as the order allows for a necessary input to a certain step to be obtained from an output of an earlier step. In addition, the steps of method 300 are performed automatically (e.g., by computer 101 of FIG. 1, or by any other applicable component of computing environment 100, or by an IC), unless specifically stated otherwise.

In a step 302, an NSC polar codes decoder may be trained, in the manner described above, in order to generate a trained NSC polar codes decoder 304 that includes the following ANNs: an input/output statistics ANN 304a (depending on whether the decoder 304 is to be used for communication or for decompression, respectively); a check-node ANN 304b; a bit-node ANN 304c; and a soft decision operations ANN 304d.

The training may include determining parameters for the ANNs 304a-304d by estimating mutual information (MI) for each of the multiple communication channels.

In the communication use case, the training may be aimed at enabling the trained NSC polar codes decoder 304 to decode data received over multiple communication channels. In the decompression use case, the training may be aimed at enabling the trained NSC polar codes decoder 304 to decompress data.

In a step 306, polar codes may be designed based on the trained NSC polar codes decoder 304. Their design may include determining, using a Monte Carlo (MC) evaluation, which of multiple communication channels are clean.

In a step 308, the trained NSC polar codes decoder 304 may be used for communication or for decompression. In the communication use case, this may include decoding data that was previously encoded using the designed polar codes and then transmitted. In the decompression use case, this may include decompressing data that was previously compressed using the designed polar codes.

### Data-Driven Neural Polar Decoder for Compression and Decompression

This section further discusses how the above technique, that generally pertains to data encoding and decoding for communication, may be adapted for the case of compression/decompression of data.

Let

$${𝒟}_{𝒩}^{ℳ} = {\{ {X}_{i , 1}^{N} \}}_{i = 1}^{M}$$

be a collection of M observations of

$${X}_{1}^{N} {∼}^{i . i . d .} {P}_{{X}_{1}^{N}} .$$

The goal is to provide a data-driven neural polar codes decoder to enable the compression of X^{N} to U^{K}, where K<N. The method here may generally include the following procedures: The first procedure is training and construction, in which the parameters of the neural polar decoder and the information set [symbol] ⊂[N] are determined. The second procedure is the encoding (compression) and the third procedure is the decoding (decompression).

A neural polar decoder for compression/decompression may be defined by E_{θ}_{₁}∈R^{d} and F_{θ}_{₂}, G_{θ}_{₃}, H_{θ}_{₄}∈ [symbol] with parameters θ=θ₁, θ₂, θ₃, θ₄, θ∈Θ. The NNs satisfy:
E_{θ}∈ε⊂R^{d} is the source (input) statistics parameters;
E_{θ}: ε×ε→ε is the check-node NN;
G_{θ}: ε×ε×\cX→ε is the bit-node NN; and
H_{θ}: ε♯[0,1] is the soft decision NN.

### Training and Construction:

Application of Algorithm 3, data-driven polar code construction for sources characterized by memory and non-i.i.d. input distributions. The procedure may commence by initializing the weights for the models E_{θ}, G_{θ}, F_{θ}, and H_{θ}. Each iteration involves sampling a sequence

$${x}_{1}^{N}$$

from a dataset

$${𝒟}_{𝒩}^{ℳ} ,$$

which is then processed through G_{N} to generate

$${u}_{1}^{N} .$$

The model E_{θ} duplicates to produce

$${e}_{X}^{N}$$

and calculates losses [symbol] ᵢ for each sequence element that is used to optimize the parameters of the neural polar decoder. After the training, the construction is performed in the same manner as done for communication channels to obtain the clean set [symbol] .

### Encoding (Compression) and Decoding (Decompression):

The encoding of X^{N} (the uncompressed data, such as a digital file) is straightforward given [symbol] and a trained E_{θ*}, G_{θ*}, F_{θ*}, H_{θ*}. Given X^{N}, the encoder computes U^{N}=X^{N}G_{N} and saves {Uᵢ: i∈ [symbol] } as the compressed version of X^{N}.

The decoding procedure may include the following steps. Given U^{K}, the frozen bits are determined, and the neural polar decoder uses a SC scheme using E_{θ*}, G_{θ*}, F_{θ*}, H_{θ*} to decode the bits [symbol] The estimated bits [symbol] are then used to compute the desired [symbol] = [symbol] G_{N}, and produce the decompressed data.

### EXPERIMENTAL RESULTS

This section presents experiments on memoryless channels and channels with memory, for both uniform and non-uniform input distributions. The experiments demonstrate the performance of the proposed algorithms for symmetric and asymmetric input distributions. All the polar codes in this section, unless specified otherwise, are designed with rate R=0.25. In all experiments, unless specified otherwise, for both memoryless channels and channel with memory, the channel embedding dimension is chosen to be d=8 and all NNs have one hidden layer with 50 units.

With respect to memoryless channels, the following experiments test the present methodology to design polar codes for various memoryless channels. To demonstrate the current algorithm, the experiments were conducted on both symmetric and asymmetric dmc. The binary symmetric channel (BSC) and the additive white Gaussian noise (AWGN, see X. Song, Z. Zhang, J. Wang, and K. Qin, “A Graph-Neural-Network Decoder With MLP-Based Processing Cells for Polar Codes,” in 2019 11^{th} International Conference on Wireless Communications and Signal Processing (WCSP), IEEE, pp. 1-6, 2019) channels are chosen as instances of symmetric channels. An asymmetric binary errasure channel (BEC), as defined in the Honda-Yamamoto scheme, is chosen as an instance of an asymmetric DMC. To validate the numerical results, the present algorithms are compared with the SC decoder that provides the optimal decoding rule under the SC decoding scheme.

The BSC channel is defined by W(y|x)=p [symbol] [y≠x]+(1−p) [symbol] [y=x]; here, p=0.1 is chosen. The AWGN channel is defined by the following relation Y=X+N, where X is the channel input, Y is the channel output and N˜ [symbol] (0, σ²) is an i.i.d. Gaussian noise with σ²=0.5. The asymmetric BEC is defined by two erasures probabilities, ϵ₀, ϵ₁, namely the probabilities for an erasure of the “0” symbol and the “1” symbol, respectively. Accordingly, W(x|x)=1−ϵₓ, W(?|x)=ϵₓ for x∈{0,1}. Similar to Honda and Yamamoto, ϵ₀=0.4, ϵ₁=0.8159 are chosen here.

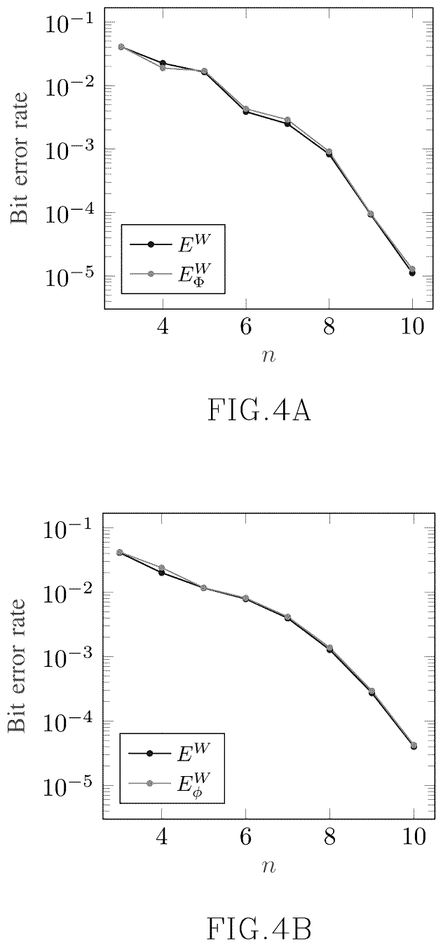

FIGS. 4A and 4B show the application of Algorithm 1 on the BSC and the AWGN channels. They report the obtained BER by Algorithm 1 in comparison with the SC decoder. FIG. 4A compares the BER incurred by Algorithm 1 and the SC decoder on a BSC with parameter 0.1. FIG. 4B compares the BER incurred by Algorithm 1 and the SC decoder on a AWGN channel. In these two figures, the curves labeled by

$${E}^{W} , {E}_{Φ}^{W}$$

correspond to the analytic and estimated channel embedding, respectively.

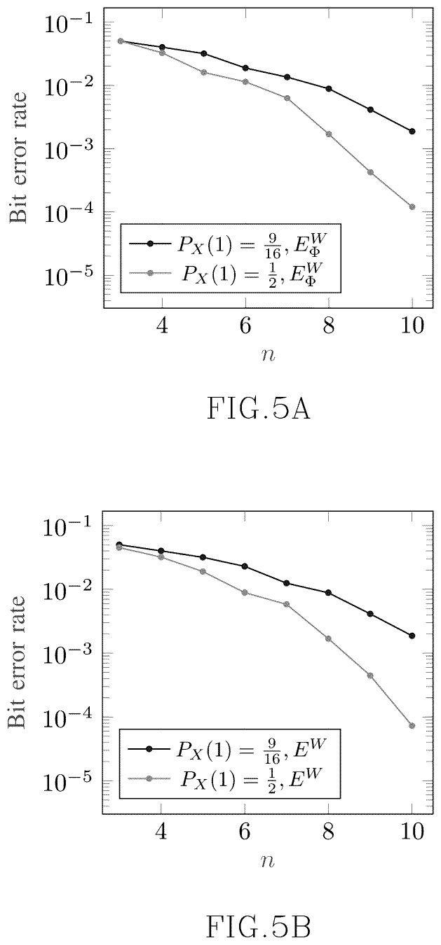

FIGS. 5A and 5B illustrate two comparisons. The first compares the BER obtained via the extension of Algorithm 1 to the Honda-Yamamoto scheme, and by the optimal decoding rule of the Honda-Yamamoto scheme. It also compares the BER obtained by a symmetric input distribution with the capacity achieving input distribution. In opposite to what was expected, better BER were obtained via a symmetric input distribution. The reason for this stems from the polarization of the source

$${U}_{1}^{N} ,$$

which has negative effect in short blocks.

FIGS. 5A and 5B, namely, compare the BERs incurred on the asymmetric BEC; both compare the results for P_{X}(1)=0.5 and

$${P}_{X} ( 1 ) = \frac{9}{16}$$

(capacity achieving input distribution). FIG. 5A compares the BERs incurred by applying the memoryless algorithm (Algorithm 1) for both choices of P_{X}. FIG. 5B is the ground truth of FIG. 5A by using E_{W} instead of

$${E}_{W}^{Φ} .$$

For channels with memory, the experiments described below demonstrate the performance of the NSC decoder on various channels. First, having a sample [symbol] _{M,N} does not indicate if it is drawn from channel with or without memory. As memoryless channels are a special case of channels with memory, the inventors started by testing the NSC on memoryless channels. The experiments proceed to FSC for which there exists an analytic polar decoder that is given by the SCT decoder (see Wang 2015). Recall that the computational complexity of the set decoder is O(| [symbol] |³ N log N); therefore, the present algorithms were evaluated on channels with a small state space and on channels with a large state space, i.e. | [symbol] |³>>N log N. The last experiments test the NSC decoder on channels with infinite state space for which an optimal decision rule is intractable.

As instances of channels with memory, the Ising channel (E. Ising, “Beitrag zur theorie des ferromagnetismus,” Zeitschrift fur Physik, vol. 31, no. 1, pp. 253-258, 1925) and the ISI channel (T. M. Cover and J. A. Thomas, Elements of Information Theory, 2nd. New-York: Wiley, 2006) were chosen, respectively. These channels belong to the family of FSCs, and therefore, their optimal decoding rule is given by the SCT decoder. The present methodology ws also tested on channels with continuous state space for which the SCT decoder cannot be applied. As an instance of such channels, the moving average additive Gaussian noise (MA-AGN) channel was chosen.

The Ising channel is defined by Y=X or Y=S with equal probability, and S′=X, where X is the channel input, Y is the channel output, S is the channel states at the beginning of the transmission and S′ is the channel's state at the end of the transmission. The interference channel is defined by the formula

$${Y}_{t} = {\sum }_{i = 0}^{r} {h}_{i} {X}_{t - i} + {Z}_{i} ,$$

where Xₜ, Yₜ are the channel input and output at time t,

$${\{ {h}_{i} \}}_{i = 1}^{r}$$

are the interference parameters, and Zᵢ [symbol] (0, σ²). In the experiment,

$${h}_{i} = \frac{{0.9}^{i}}{10}$$

and σ²=0.5 were set. Accordingly, the Ising channel has state size of | [symbol] |=2 and the ISI channel has state size of | [symbol] |=2^{r}. The MA-AGN channel is given by Yₜ=Xₜ+\tilde{Z}ₜ, \tilde{Z}ₜ=Zₜ+αZₜ₋₁, where α∈ [symbol] and Zₜ [symbol] (0, σ²).

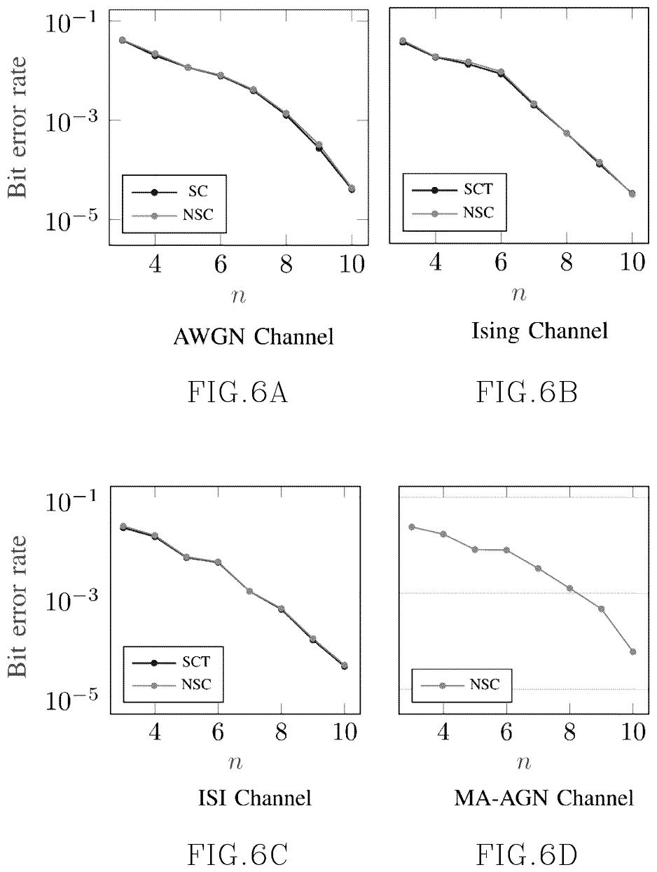

FIGS. 6A-6D compare the BER attained by Algorithm 3 vs. the optimal decoding rule (ground truth given by the SCT decoder) for the AWGN, Ising, ISI with r=2, and the MA-AGN channel with α=0.9, respectively. For the last channel, FIG. 6D, the incurred BERs are illustrated without any comparison, since an SC decoding rule for a channel with a continuous state space could not be located.

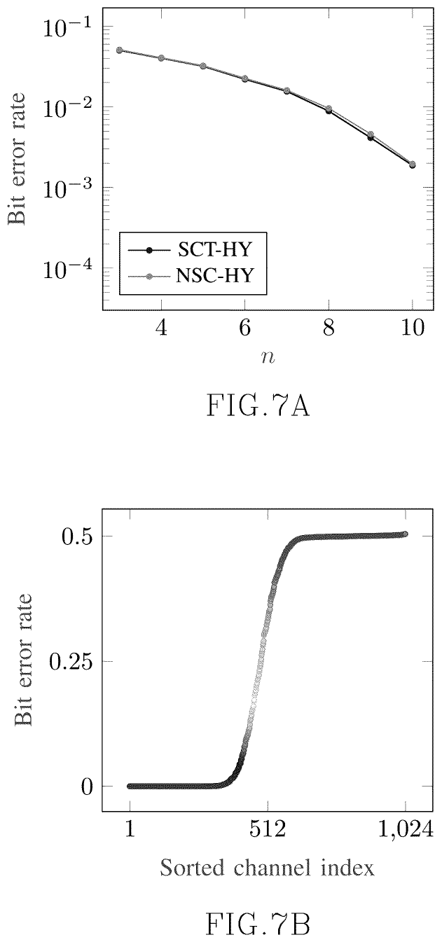

FIGS. 7A and 7B show the incurred BERs for all synthesized channels in order to illustrate the channel polarization and the attained performance. FIG. 7A illustrates the BERs attained by Algorithm 4 on the Ising channel with an input distribution with memory. That is the incurred BER for the case where the input distribution is given by

$${P}_{{X}_{i} \vert {X}_{i - 1}} ( x \vert y ) = \{ \begin{matrix}0.4 & x = y \\ 0.6 & x \neq y\end{matrix} .$$

This distribution was chosen, rather than the attained input distribution from the DINE algorithm, in order to be able to compare the present approach with the SCT decoder. FIG. 7B illustrates the polarization of the synthesized bit channels for the Ising channel.

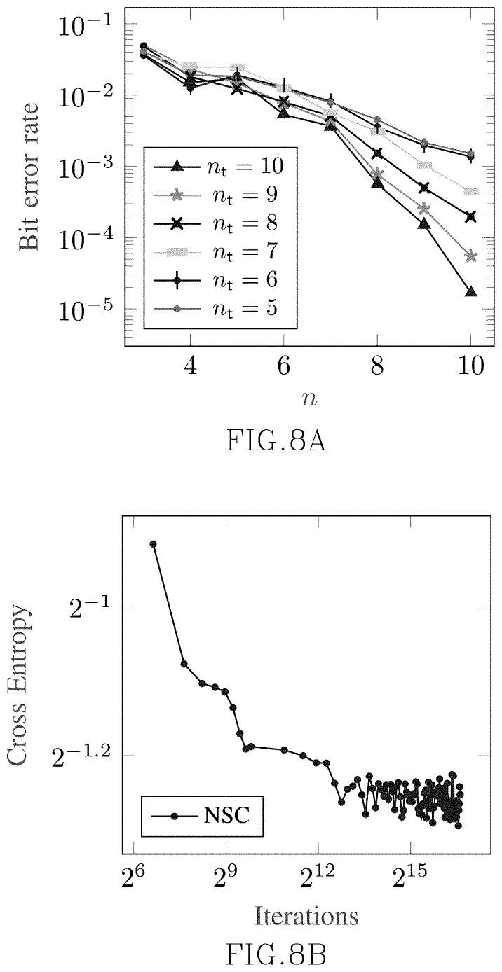

FIGS. 8A and 8B show the convergence of Algorithm 3 when applied on the Ising channel. FIG. 8A illustrates the BER incurred for varying values of nₜ, the block length in training. It is clear that increasing nₜ produces better estimation results. FIG. 8B illustrates the CE convergence as a function of training iterations.

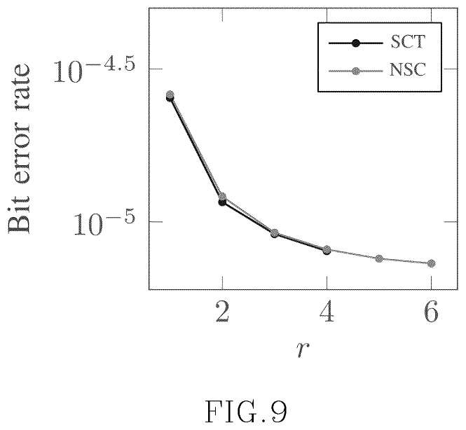

FIG. 9 compares the complexity of the NSC and SCT decoders and demonstrates the decoding performance of both decoders on the ISI channel. In the decoding performance, the SCT decoder was simulated only up to r=4 due to its immense memory requirements.

Table 1 provides a comparison of the computational complexity of the SCT decoder and the NSC decoder on the ISI channel for varying values of r. The complexity of the NSC corresponds for d=8 and the NNs have 50 hidden units. Notably, the computational complexity of the NSC decoder does not increase with r.

TABLE 1

| r | SCT | NSC |
|---|---|---|
| 1 | 0(2³NlogN) | 0(800NlogN) |
| 2 | 0(2⁶NlogN) | 0(800NlogN) |
| 3 | 0(2⁹NlogN) | 0(800NlogN) |
| 4 | 0(2¹²NlogN) | 0(800NlogN) |
| 5 | 0(2¹⁵NlogN) | 0(800NlogN) |
| 6 | 0(2¹⁸NlogN) | 0(800NlogN) |

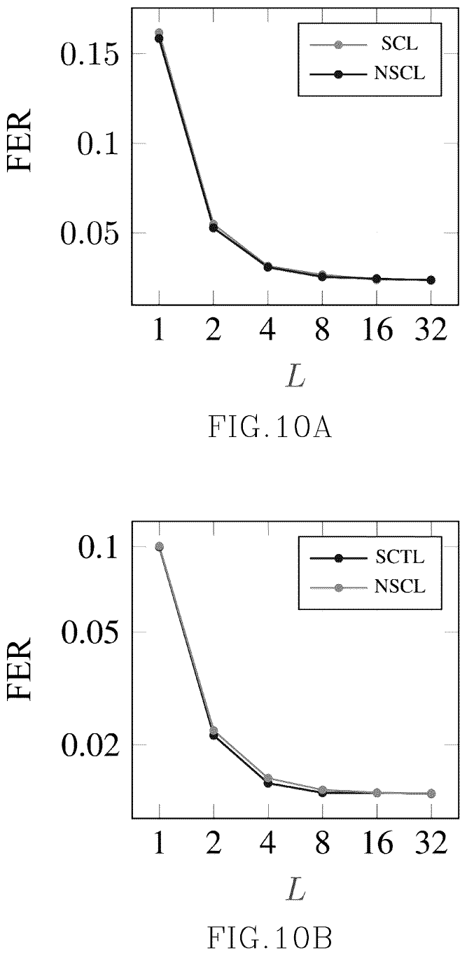

FIGS. 10A and 10B compare the performance of the NSC list decoder (denoted NSCL) with that of the SCL decoder. The AWGN channel was selected as an example of a memoryless channel. In the experiments, σ²=1.5. These figures illustrate the FER obtained via the SCL decoder with the FER obtained via the NSC list decoder as a function of the list size L. FIG. 10A demonstrates the results for the AWGN channel with a signal-to-noise ratio (SNR) of 1.5, while FIG. 10B compares the results for the Ising channel. As can be seen in these figures, the NSC list decoder indeed converges to the ground truth SCL decoder for both channels.

The set up and parameters of each of the experiments discussed above form optional embodiments according to aspects of the invention.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, or any suitable combination of the foregoing. Some known types of storage devices that include these mediums include: hard drive (magnetic or solid-state), random access memory (RAM), read-only memory (ROM), erasable programmable read-only memory (EPROM or Flash memory), static random access memory (SRAM), compact disc read-only memory (CD-ROM), digital versatile disk (DVD), or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

In the description and claims, each of the terms “substantially,” “essentially,” and forms thereof, when describing a numerical value, means up to a 20% deviation (namely, ±20%) from that value. Similarly, when such a term describes a numerical range, it means up to a 20% broader range—10% over that explicit range and 10% below it).

In the description, any given numerical range should be considered to have specifically disclosed all the possible subranges as well as individual numerical values within that range, such that each such subrange and individual numerical value constitutes an embodiment of the invention. This applies regardless of the breadth of the range. For example, description of a range of integers from 1 to 6 should be considered to have specifically disclosed subranges such as from 1 to 3, from 1 to 4, from 1 to 5, from 2 to 4, from 2 to 6, from 3 to 6, etc., as well as individual numbers within that range, for example, 1, 4, and 6. Similarly, description of a range of fractions, for example from 0.6 to 1.1, should be considered to have specifically disclosed subranges such as from 0.6 to 0.9, from 0.7 to 1.1, from 0.9 to 1, from 0.8 to 0.9, from 0.6 to 1.1, from 1 to 1.1 etc., as well as individual numbers within that range, for example 0.7, 1, and 1.1.

The descriptions of the various embodiments of the present invention have been presented for purposes of illustration, but are not intended to be exhaustive or limited to the explicit descriptions. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the description and claims of the application, each of the words “comprise,” “include,” and “have,” as well as forms thereof, are not necessarily limited to members in a list with which the words may be associated.

Where there are inconsistencies between the description and any document incorporated by reference or otherwise relied upon, it is intended that the present description controls.

1. A method comprising:
using a neural successive cancellation (NSC) polar codes decoder for communication or decompression, wherein the NSC polar codes decoder comprises the following Artificial Neural Networks (ANNs):
(a) when the NSC polar codes decoder is used for communication: an output statistics ANN,
(b) when the NSC polar codes decoder is used for decompression: an input statistics ANN,
(c) a check-node ANN,
(d) a bit-node ANN, and
(e) a soft decision operations ANN.

2. The method of claim 1, wherein the NSC polar codes decoder is used for decompression, and wherein the method further comprises designing polar codes to compress data, the designing being based on the NSC polar codes decoder.

3. The method of claim 2, further comprising training the ANNs to decompress the compressed data.

4. The method of claim 1, wherein the NSC polar codes decoder is used for communication, and wherein the method further comprises designing polar codes to encode data to be transmitted over multiple communication channels, the designing being based on the NSC polar codes decoder.

5. The method of claim 4, further comprising training the ANNs to decode the data after the data have been received over the multiple communication channels.

6. The method of claim 5, wherein the training comprises determining parameters for the ANNs by estimating mutual information (MI) for each of the multiple communication channels.

7. The method of claim 6, wherein the designing of the polar codes comprises determining, using a Monte Carlo (MC) evaluation, which of the multiple communication channels are clean.

8. The method of claim 5, wherein the ANNs of (a), (c), (d), and (e) are trained jointly.

9. The method of claim 6, wherein the ANN of (a) is trained first, and the ANNs of (c), (d), and (e) are then trained while maintaining the determined parameters of the ANN of (a) fixed.

10. The method of claim 4, wherein a channel model of each of the multiple communication channels is unknown.

11. The method of claim 4, wherein:
the multiple communication channels are communication channels with memory; and
a computational complexity of the NSC polar codes decoder is not affected by the size of the memory.

12. A system comprising:
(i) at least one hardware processor; and
(ii) a non-transitory computer-readable storage medium having program code embodied therewith, the program code executable by said at least one hardware processor to use a neural successive cancellation (NSC) polar codes decoder for communication or decompression, wherein the NSC polar codes decoder comprises the following Artificial Neural Networks (ANNs):
(a) when the NSC polar codes decoder is used for communication: an output statistics ANN,
(b) when the NSC polar codes decoder is used for decompression: an input statistics ANN,
(c) a check-node ANN,
(d) a bit-node ANN, and
(e) a soft decision operations ANN.

13. The system of claim 12, wherein the NSC polar codes decoder is used for decompression, and wherein the program code is further executable to design polar codes to compress data, the designing being based on the NSC polar codes decoder.

14. The system of claim 13, wherein the program code is further executable to train the ANNs to decompress the compressed data.

15. The system of claim 12, wherein the NSC polar codes decoder is used for communication, and wherein the program code is further executable to design polar codes to encode data to be transmitted over multiple communication channels, the designing being based on the NSC polar codes decoder.

16. The system of claim 15, wherein the program code is further executable to train the ANNs to decode the data after the data have been received over the multiple communication channels.

17. The system of claim 16, wherein the training comprises determining parameters for the ANNs by estimating mutual information (MI) for each of the multiple communication channels.

18. The system of claim 17, wherein the designing of the polar codes comprises determining, using a Monte Carlo (MC) evaluation, which of the multiple communication channels are clean.

19. The system of claim 16, wherein the ANNs of (a), (c), (d), and (e) are trained jointly.

20. The system of claim 17, wherein the ANN of (a) is trained first, and the ANNs of (c), (d), and (e) are then trained while maintaining the determined parameters of the ANN of (a) fixed.

21. The system of claim 15, wherein a channel model of each of the multiple communication channels is unknown.

22. The system of claim 15, wherein:
the multiple communication channels are communication channels with memory; and
a computational complexity of the NSC polar codes decoder is not affected by the size of the memory.

23. A computer program product comprising a non-transitory computer-readable storage medium having program code embodied therewith, the program code executable by at least one hardware processor to:
use a neural successive cancellation (NSC) polar codes decoder for communication or decompression, wherein the NSC polar codes decoder comprises the following Artificial Neural Networks (ANNs):
(a) when the NSC polar codes decoder is used for communication: an output statistics ANN,
(b) when the NSC polar codes decoder is used for decompression: an input statistics ANN,
(c) a check-node ANN,
(d) a bit-node ANN, and
(e) a soft decision operations ANN.

24. The computer program product of claim 23, wherein the NSC polar codes decoder is used for decompression, and wherein the program code is further executable to design polar codes to compress data, the designing being based on the NSC polar codes decoder.

25. The computer program product of claim 24, wherein the program code is further executable to train the ANNs to decompress the compressed data.

26. The computer program product of claim 23, wherein the NSC polar codes decoder is used for communication, and wherein the program code is further executable to design polar codes to encode data to be transmitted over multiple communication channels, the designing being based on the NSC polar codes decoder.

27. The computer program product of claim 26, wherein the program code is further executable to train the ANNs to decode the data after the data have been received over the multiple communication channels.

28. The computer program product of claim 27, wherein the training comprises determining parameters for the ANNs by estimating mutual information (MI) for each of the multiple communication channels.

29. The computer program product of claim 28, wherein the designing of the polar codes comprises determining, using a Monte Carlo (MC) evaluation, which of the multiple communication channels are clean.

30. The computer program product of claim 27, wherein the ANNs of (a), (c), (d), and (e) are trained jointly.

31. The computer program product of claim 28, wherein the ANN of (a) is trained first, and the ANNs of (c), (d), and (e) are then trained while maintaining the determined parameters of the ANN of (a) fixed.

32. The computer program product of claim 26, wherein a channel model of each of the multiple communication channels is unknown.

33. The computer program product of claim 26, wherein:
the multiple communication channels are communication channels with memory; and
a computational complexity of the NSC polar codes decoder is not affected by the size of the memory.

34. A semiconductor Integrated Circuit (IC) comprising:
a neural successive cancellation (NSC) polar codes decoder configured with the following Artificial Neural Networks (ANNs):
(a) an output statistics ANN,
(b) a check-node ANN,
(c) a bit-node ANN, and
(d) a soft decision operations ANN; and
a polar codes encoder configured to encode data using polar codes designed based on the NSC polar codes decoder.

35. The semiconductor IC of claim 34, further comprising circuitry to train the ANNs of the NSC polar codes decoder.

36. The semiconductor IC of claim 35, wherein the training comprises determining parameters for the ANNs by estimating mutual information (MI) for each of multiple communication channels.

37. The semiconductor IC of claim 36, wherein the polar codes encoder is configured to design the polar codes by determining, using a Monte Carlo (MC) evaluation, which of the multiple communication channels are clean.

38. The semiconductor IC of claim 35, wherein the ANNs of (a), (c), (d), and (e) are trained jointly.

39. The semiconductor IC of claim 35, wherein the ANN of (a) is trained first, and the ANNs of (c), (d), and (e) are then trained while maintaining the determined parameters of the ANN of (a) fixed.

40. The semiconductor IC of claim 36, wherein a channel model of each of the multiple communication channels is unknown.

41. The semiconductor IC of claim 36, wherein:
the multiple communication channels are communication channels with memory; and
a computational complexity of the NSC polar codes decoder is not affected by the size of the memory.

42. A computer-readable medium having stored thereon a computer-readable encoding of the semiconductor integrated circuit (IC) of claim 34.
